(19) United States
(12) Patent Application Publication
(10) Pub. No.: US 2026/0369319 A1
(43) Pub. Date: Nov. 19, 2026

(54) METHOD OF OPERATING MEMORY DEVICE

(71) Applicant: TAIWAN SEMICONDUCTOR MANUFACTURING COMPANY, LTD., Hsinchu (TW)

(72) Inventors: Elia AMBROSI, Hsinchu (TW); MingYuan SONG, Hsinchu (TW); Xinyu BAO, Hsinchu (TW)

(21) Appl. No.: 19/754,716

(22) Filed: Jul. 27, 2026

Related U.S. Application Data
(62) Division of application No. 18/745,121, filed on Jun. 17, 2024.

(51) Int. Cl. G11C 13/00

(52) U.S. Cl. CPC G11C 13/004; G11C 13/0028

(57) ABSTRACT

A method includes a computing-in-memory (CIM) operation of a memory device. The memory device includes memory arrays each including a bit line, word lines and memory cells coupled to the bit line and correspondingly to the word lines. In the CIM operation, the method includes supplying input voltages to the word lines in each of at least two memory arrays among the memory arrays. The method further includes, for each of the at least two memory arrays, collecting, on the bit line, a bit line current corresponding to a sum of currents output by the memory cells on the bit line in response to the input voltages supplied to the word lines. The method further includes collecting a path current corresponding to a sum of the bit line currents of the at least two memory arrays.

### RELATED APPLICATION(S)

The present application is a divisional application of U.S. application Ser. No. 18/745,121, filed Jun. 17, 2024, which is incorporated herein by reference in its entirety.

### BACKGROUND

Recent developments in the field of artificial intelligence (AI) have resulted in various products and/or applications, including, but not limited to, speech recognition, image processing, machine learning, natural language processing, or the like. Such products and/or applications often use neural networks to process large amounts of data for learning, training, cognitive computing, or the like. Memory devices configured to perform computing-in-memory (CIM) operations (also referred to herein as CIM memory devices) are usable for neural network applications, as well as other applications. A CIM memory device includes a memory array configured to store weight data and/or input data to be used together in one or more CIM operations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a memory device, and FIGS. 1B-1D are schematic circuit diagrams of a section of the memory device in various operations, in accordance with some embodiments.

FIGS. 2A-2B are schematic diagrams of memory devices, in accordance with some embodiments.

FIGS. 3A-3B are schematic circuit diagrams of a section of a memory device in various operations, in accordance with some embodiments.

FIGS. 4A-4C are schematic cross-sectional views of portions of memory devices, in accordance with some embodiments.

FIG. 5A includes a schematic circuit diagram, a perspective view and a cross-sectional view of a memory cell, in accordance with some embodiments.

FIG. 5B includes a schematic circuit diagram, and a cross-sectional view of a memory cell, in accordance with some embodiments.

FIGS. 5C-5D are schematic cross-sectional views of memory cells, in accordance with some embodiments.

FIG. 6A is a schematic circuit diagram of a memory cell, in accordance with some embodiments.

FIG. 6B is a schematic cross-sectional view of a memory device, in accordance with some embodiments.

FIG. 7A is a schematic diagram of an integrated circuit (IC) device, in accordance with some embodiments.

FIG. 7B is a schematic diagram showing various operations in a machine learning process, in accordance with some embodiments.

FIG. 7C is a schematic diagram of a neural network, in accordance with some embodiments.

FIGS. 8A-8B are flowcharts of various methods, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a memory device comprises a plurality of memory arrays stacked one over another along a thickness direction of the memory device. Corresponding bit lines of the stacked memory arrays are electrically coupled to each other by an interconnect extending along the thickness direction. In a CIM operation in one or more embodiments, input voltages corresponding to input data are supplied to word lines of the stacked memory arrays. In response to the input voltages, memory cells in each of the stacked memory arrays output corresponding read currents to a bit line, and a bit line current corresponding to a sum of the read currents is collected on the bit line. Because corresponding bit lines of the stacked memory arrays are electrically coupled to each other by an interconnect, a path current corresponding to a sum of the bit line currents of the stacked memory arrays is collected on the interconnect. In at least one embodiment, the path current is supplied to a sensing circuit. Based on the sensed path current, a result of the CIM operation involving the input data and weight data stored in the memory cells of the stacked memory arrays is determined. In some embodiments, the stacked memory arrays are back-end-of-line (BEOL) structures and/or are manufactured by BEOL processes. In some embodiments, different stacked memory arrays are configured to have different resistance-area products (RAs). In some embodiments, different stacked memory arrays are manufactured with different memory technologies and/or to have different memory cell configurations. In some embodiments, memory cells of different stacked memory arrays are combined to encode multiple conductance levels. In at least one embodiment, the described memory device and/or CIM operation make it possible to achieve one or more advantages, including, but not limited to, increased memory density without decreasing area efficiency, three-dimensional (3D) matrix-vector multiplication (MVM), multi-level conductance combination and/or optimization, stability improvement, or the like. In some embodiments, one or more devices, methods, operations, advantages described herein are applicable or achievable in applications other than CIM applications.

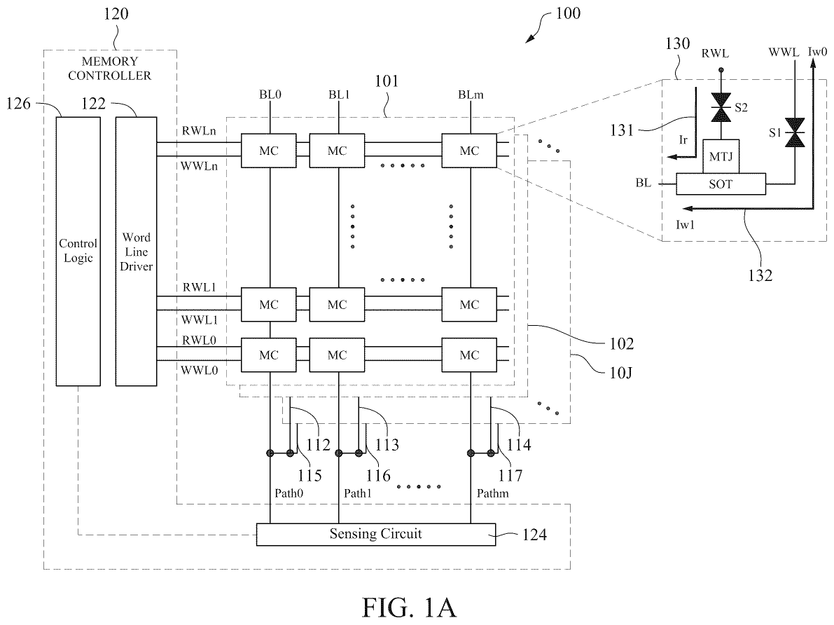

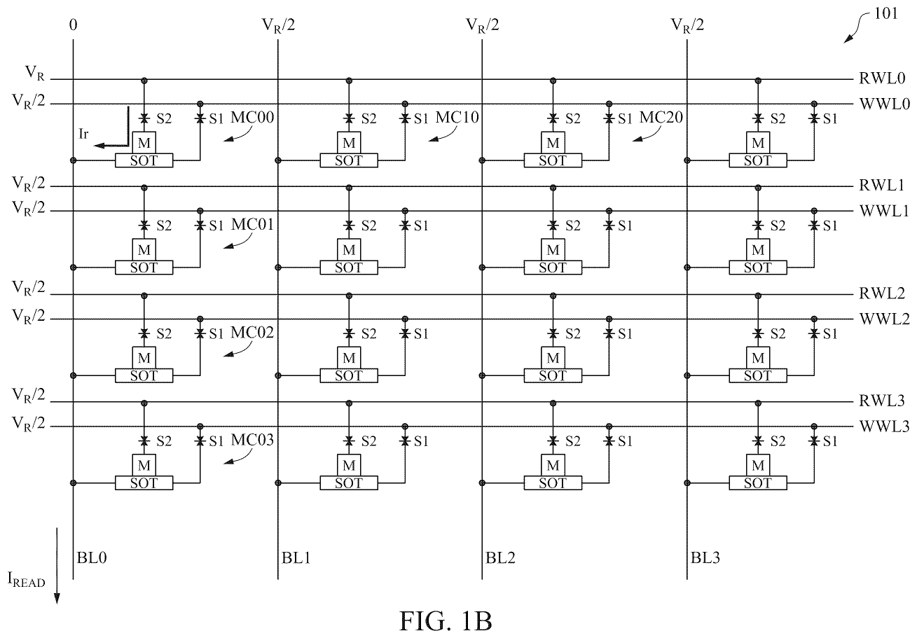

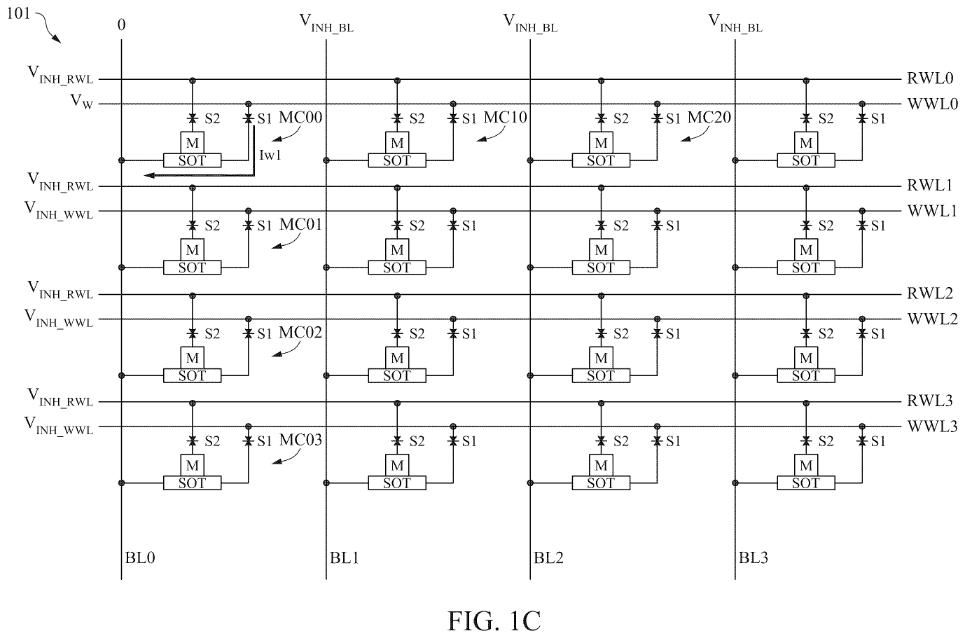

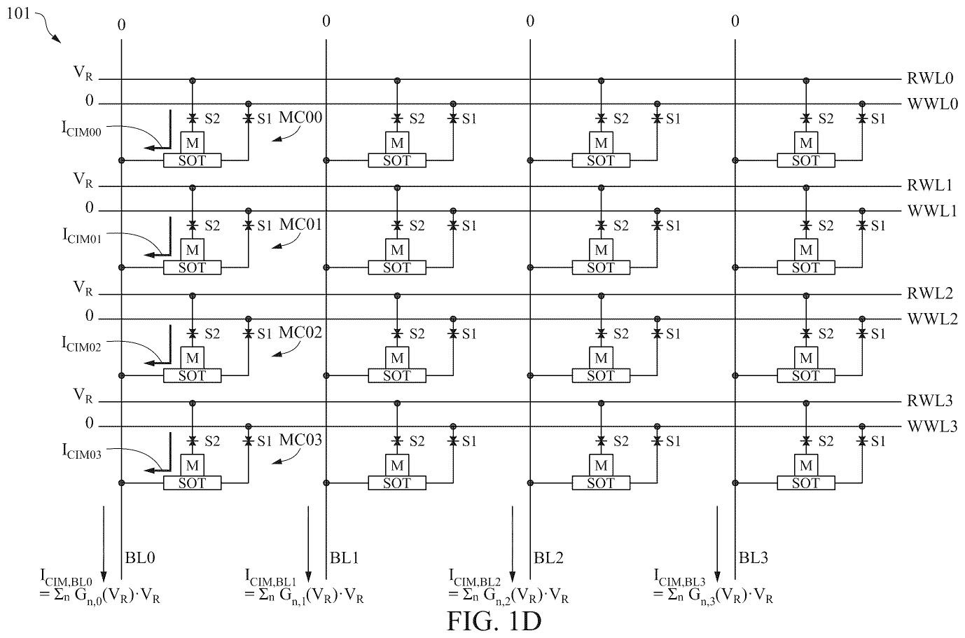

FIG. 1A is a schematic diagram of a memory device 100, in accordance with some embodiments. A memory device is a type of integrated circuit (IC) device. In at least one embodiment, a memory device is an individual IC device. In some embodiments, a memory device is included as a part of a larger IC device which comprises circuitry other than the memory device for other functionalities.

The memory device 100 comprises a plurality of memory arrays 101, 102, . . . 10J (where J is a natural number greater than 1), and a memory controller 120. In some embodiments, the memory arrays 101, 102, . . . 10J are stacked one over another along a thickness direction of the memory device 100, as described herein. In at least one embodiment, the memory arrays 101, 102, . . . 10J are configured similarly. A detailed description of a representative memory array, e.g., the memory array 101, is given herein.

The memory array 101 comprises a plurality of memory cells MC arranged in a plurality of columns and rows of the corresponding memory array. The memory array 101 further comprises a plurality of word lines (also referred to as “address lines”) extending along a row direction (i.e., the horizontal direction in FIG. 1A) of the rows, and a plurality of bit lines (also referred to as “data lines”) extending along a column direction (i.e., the vertical direction in FIG. 1A) of the columns. The memory controller 120 is electrically coupled, by the word lines and/or bit lines, to the memory cells MC and configured to control operations of the memory cells MC including, but not limited to, a read operation, a write operation, a CIM operation, or the like.

In the example configuration in FIG. 1A, the word lines comprise a plurality of write word lines WWL0, WWL1 to WWLn and a plurality of read word lines RWL0, RWL1 to RWLn, and the bit lines comprise bit lines BL0, BL1 to BLm, where m and n are non-negative integers. The write word lines WWL0 to WWLn are sometimes commonly referred to as “WWL”, the read word lines RWL0 to RWLn are sometimes commonly referred to as “RWL”, the word lines including write word lines and read word lines are sometimes commonly referred to herein as “WL”, and the bit lines are sometimes commonly referred to herein as “BL”. In some example operations, word lines are configured for transmitting addresses of the memory cells MC to be read from in a read operation, or for transmitting addresses of the memory cells MC to be written to in a write operation, or for transmitting input voltages to memory cells MC in a CIM operation, or the like. In some example operations, bit lines are configured for transmitting data read from the memory cells MC indicated by corresponding word lines, or for transmitting data to be written to the memory cells MC indicated by corresponding word lines, or for transmitting bit line currents in a CIM operation, or the like. In the memory device 100, each memory cell MC is coupled to a bit line BL, and a pair of word lines including a write word line WWL and a read word line RWL. An example memory cell configuration 130 of each memory cell MC is described herein. In some embodiments, the memory array 101 comprises memory cells MC of a different memory cell configuration in which each memory cell MC is coupled to a bit line BL, and a word line WL (instead of a pair of word lines). In some embodiments, the memory array 101 comprises memory cells MC of a further different memory cell configuration, and comprises a plurality of source lines (not shown) coupled to the memory cells MC along the rows or along the columns. Source lines are further examples of data lines, and are sometimes commonly referred to herein as “SL”. Various memory cell configurations and/or numbers of word lines and/or bit lines and/or source lines in a memory array are within the scope of various embodiments.

Corresponding bit lines of the memory arrays 101, 102, . . . 10J are electrically coupled to each other. For example, the memory array 102 comprises a plurality of bit lines 112, 113 to 114 corresponding to the bit lines BL0, BL1 to BLm, and the memory array 10J comprises a plurality of bit lines 115, 116 to 117 corresponding to the bit lines BL0, BL1 to BLm. The corresponding bit lines BL0, 112 to 115 of the memory arrays 101, 102, . . . 10J are electrically coupled to each other as schematically indicated by a conductor Path0, the corresponding bit lines BL1, 113 to 116 are electrically coupled to each other as schematically indicated by a conductor Path1, and the corresponding bit lines BLm, 114 to 117 are electrically coupled to each other as schematically indicated by a conductor Pathm. In some embodiments, at least one or each of the conductors Path0, Path1 to Pathm comprises an interconnect extending along the thickness direction of the memory device 100, and electrically coupling the corresponding bit lines together, as described herein. In at least one embodiment, at least one or each of the conductors Path0, Path1 to Pathm comprises one or more patterns in one or more metal layers and/or one or more vias in one or more via layers. The conductors Path0, Path1 to Pathm electrically couple the corresponding bit lines to the memory controller 120, as described herein.

The memory controller 120 is sometimes referred to as a control circuit. In the example configuration in FIG. 1A, the memory controller 120 comprises a word line driver 122, a sensing circuit 124, and a control logic 126. In some embodiments, the memory controller 120 further comprises one or more of a bit line driver, a bit line selection circuit, a buffers, a pre-charging circuit, one or more clock generators for providing clock signals for various components of the memory device 100, global address decoder circuits, pre-decoder circuits, address latches, pulse generators, timing circuits, one or more input/output (I/O) circuits for data, address, clock and/or control exchange with external circuitry, one or more sub-controllers for controlling various operations in the memory device 100, or the like.

The word line driver 122 is coupled to the memory array 101 via the word lines WL, including the write word lines WWL0 to WWLn and read word lines RWL0 to RWLn. The word line driver 122 is configured to decode a row address of the memory cell MC selected to be accessed in an access operation. The word line driver 122 is sometimes referred to as a word line decoder. The word line driver 122 is configured to supply a voltage to the selected word line WL corresponding to the decoded row address, and a different voltage to the other, unselected word lines WL. In at least one embodiment, the word line driver 122 comprises one or more driving circuits or inverters.

In some embodiments, the memory controller 120 comprises a bit line driver (not shown) coupled to the memory array 101 via the conductors Path0, Path1 to Pathm and the bit lines BL. In some embodiments, the bit line driver is selectively coupled to the conductors Path0, Path1 to Pathm and the corresponding to bit lines BL through a bit line selection circuit (not shown). Examples of the bit line selection circuit include, but are not limited to, a switch, a transistor, a multiplexer, or the like. The bit line driver is configured to decode a column address of the memory cell MC selected to be accessed in an access operation. The bit line driver is sometimes referred to as a bit line decoder. The bit line driver is configured to supply a voltage to the selected bit line BL corresponding to the decoded column address, and a different voltage to the other, unselected bit lines BL. In at least one embodiment, the bit line driver comprises one or more driving circuits or inverters. In some embodiments, the memory controller 120 further comprises a source line driver (not shown) coupled to the memory cells MC via source lines (not shown). In one or more embodiments, one or more of the word line driver 122, the bit line driver, the source line driver are part of circuitry referred to as a read/write driver or a read/write decoder.

The sensing circuit 124 is configured to perform a read operation or a CIM operation, when coupled to a selected bit line BL by a corresponding conductor among the conductors Path0, Path1 to Pathm. In some embodiments, the sensing circuit 124 is selectively coupled to the selected bit line BL and the corresponding conductor through the bit line selection circuit. In some embodiments, the sensing circuit 124 comprises a sense amplifier. In at least one embodiment, the sensing circuit 124 further comprises a buffer for temporarily storing data. Example buffers include, but are not limited to, registers, memory cells, or other circuit elements configured for data storage. Other configurations of the sensing circuit 124 and/or buffers are within the scopes of various embodiments. In a read operation in one or more embodiments, the sense amplifier is configured to sense a read current on the bit line coupled to a selected memory cell MC and the sensing circuit 124. The sensing circuit 124 or a further circuit of the memory controller 120 is configured to output a datum stored in and read from the selected memory cell MC, based on the sensed read current. In a CIM operation in at least one embodiment, the sense amplifier is configured to sense a path current on a conductor among the conductors Path0, Path1 to Pathm. The sensing circuit 124 or a further circuit of the memory controller 120 is configured to output a result of the CIM operation, based on the sensed path current.

In some embodiments, the memory controller 120 further comprises a multiply-accumulate (MAC) circuit (not shown) operable in a CIM operation. For example, a MAC circuit comprises one or more accumulators and one or more analog-to-digital converters (ADCs). Example accumulators include, but are not limited to, resistors, capacitors, integrator circuits, operational amplifiers, combinations thereof, or the like. Example ADCs include, but are not limited to, logics, integrated circuits, comparators, counters, registers, combinations thereof, or the like. In some embodiments, an integrator circuit of the MAC circuit is electrically coupled to the sensing circuit 124 to receive the sensed path current in a CIM operation, and is configured to, based on the sensed path current, generate an output voltage having a voltage value corresponding to a current value of the sensed path current. In at least one embodiment, it is easier in subsequent processing to use the voltage value of the output voltage than to use the current value of the sensed path current to determine a result of the CIM operation. The described MAC circuit configuration having accumulators and ADCs is an example. Other MAC circuit configurations are within the scopes of various embodiments.

The control logic 126 is an example of one or more sub-controllers and/or further circuits included in the memory controller 120, and is configured to control other components and various operations in the memory device 100. In the example configuration in FIG. 1A, the control logic 126 is coupled to the word line driver 122 and the sensing circuit 124, and is configured to control the word line driver 122 and/or the sensing circuit 124 in an access operation, including a read operation, a write operation, and/or a CIM operation, as described herein. The control logic 126, or one or more further sub-controllers and/or further circuits of the memory controller 120, is/are coupled to and configured to control one or more of a bit line selection circuit, a current summation circuit, a bit line driver, buffers, computation circuits, I/O circuits, or the like, to coordinate operations of these circuits, drivers and/or buffers in such an access operation of the memory device 100. In one or more embodiments, the control logic 126 comprises one or more circuits of one or more of transistors, switches, logic gates, multiplexers, flip-flops, latches, or the like. The described configurations of memory arrays and/or memory controllers are examples. Other memory array and/or memory controller configurations are within the scopes of various embodiments.

In the example configuration in FIG. 1A, the memory cells MC have the memory cell configuration 130 which is a spin-orbit torque (SOT) magnetoresistive random-access memory (MRAM) configuration. SOT MRAM is an example of non-volatile memory (NVM). Other types or technologies of NVM are within the scopes of various embodiments, including, but not limited to, spin-transfer torque (STT) MRAM, resistive RAM (RRAM or ReRAM), phase-change memory (PCM), ferroelectric RAM (FeRAM), electrochemical RAM (ECRAM), or the like. In the memory cell configuration 130, the memory cell MC comprises a magnetic tunnel junction (MTJ) structure, a SOT layer in contact with the MTJ structure, a first selector S1 coupled in series with the SOT layer between a bit line BL and a write word line WWL, and a second selector S2 coupled between the MTJ structure and a read word line RWL.

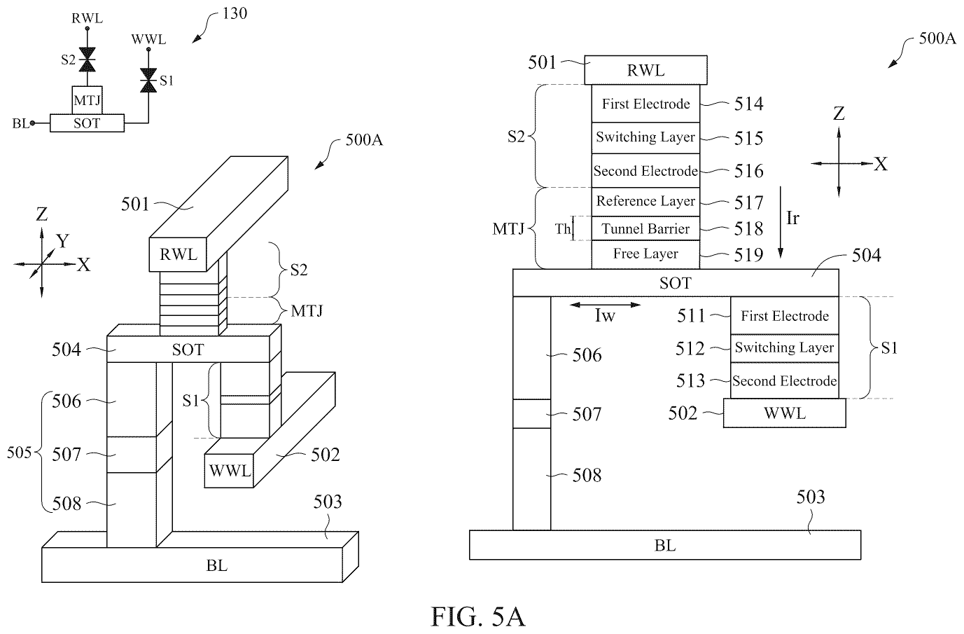

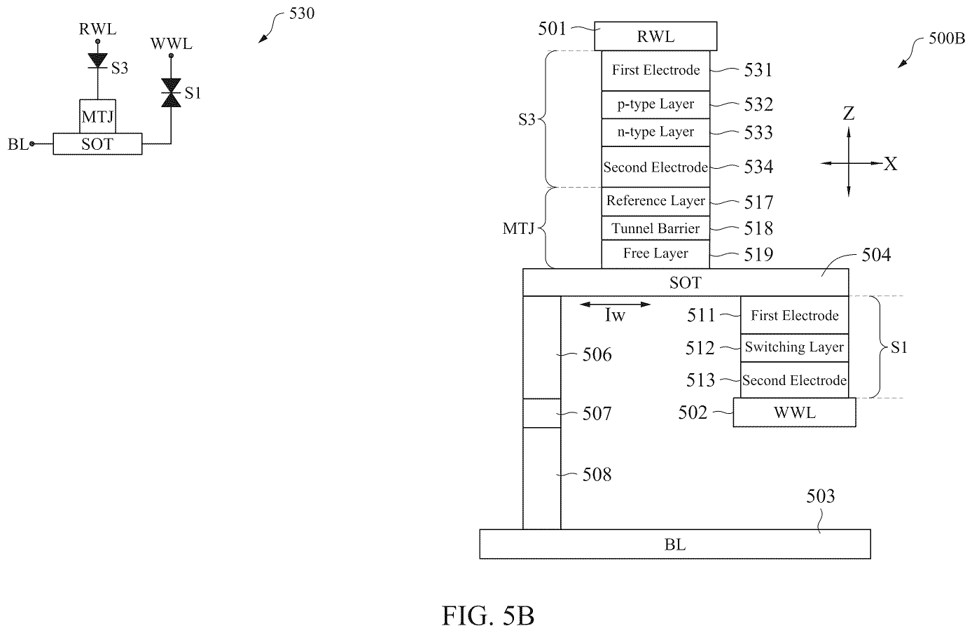

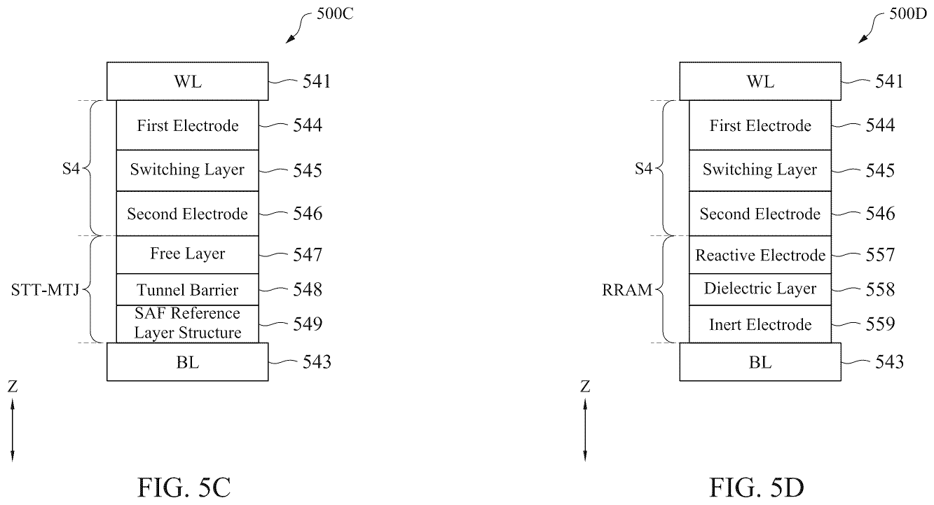

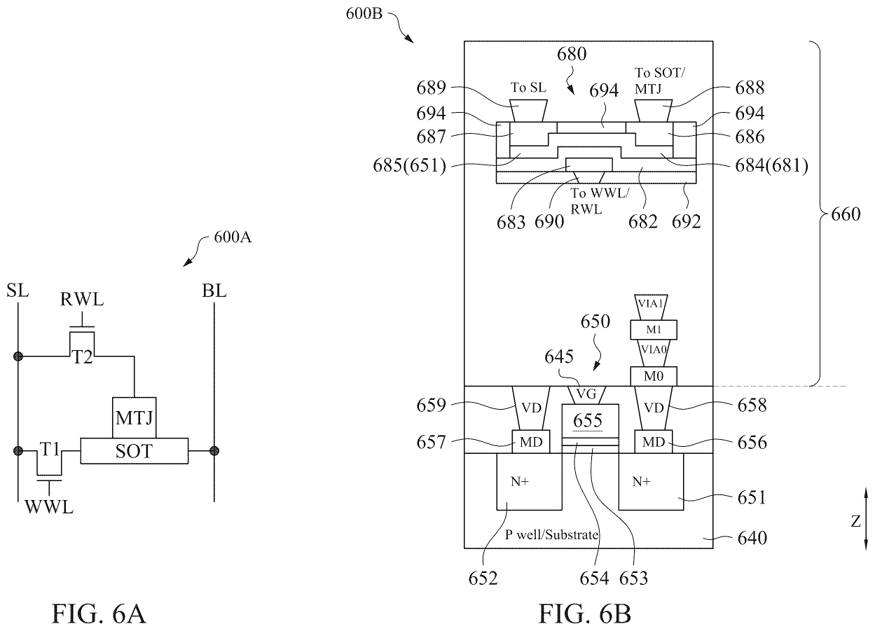

The MTJ structure comprises a free magnetic layer (sometimes referred to as “free layer”), a reference magnetic layer (sometimes referred to as “fixed layer” or “reference layer”), and a tunnel barrier layer between the free layer and the reference layer. The MTJ structure is configured to store a datum. The SOT layer is configured to enable the datum to be written, or stored, into the MTJ structure. Each of the selector S1 and selector S2 is a bi-directional circuit element configured to control a current to flow, or not to flow therethrough. In some embodiments, a selector is configured to be turned ON to pass current therethrough, in response to a bias (or bias voltage) applied across the selector being at or greater than a threshold voltage. A sign (positive or negative) of the bias corresponds to a direction of the current passing through the selector. In response to a bias applied across the selector being smaller than the threshold voltage, the selector is configured to be turned OFF. A detailed description of example configurations of the MTJ structure, SOT layer and the selectors S1, S2 is provided with respect to FIG. 5A. In some embodiments, the selector S2 is replaced with a diode, for example, as described with respect to FIG. 5B. In at least one embodiment, the selectors S1, S2 are replaced with transistors, for example, as described with respect to FIG. 6A.

A datum stored in the MTJ structure corresponds to a magnetization of the free layer relative to a magnetization of the reference layer. For example, when the magnetization of the free layer is anti-parallel to the magnetization of the reference layer, the MTJ structure is in a high resistance state (or AP state) corresponding to a first logic state, e.g., one of logic “1” and logic “0”. When the magnetization of the free layer is parallel to the magnetization of the reference layer, the MTJ structure is in a low resistance state (or P state) corresponding to a second logic state, e.g., the other of logic “1” and logic “0”. The SOT layer is configured to set the MTJ structure into one of the first logic state and the second logic state. For example, when a current is caused to flow through the SOT layer in a first direction, the free layer is caused to have a magnetization anti-parallel to the magnetization of the reference layer, corresponding to the first logic state being stored in the MTJ structure. When a current is caused to flow through the SOT layer in a second direction opposite to the first direction, the free layer is caused to have a magnetization parallel to the magnetization of the reference layer, corresponding to the second logic state being stored in the MTJ structure. Examples of various access operations, e.g., under control of the memory controller 120, are described below.

In an example read operation of the memory cell MC, an inhibition bias is applied across the selector S1 to turn OFF the selector S1 and/or to suppress sneak currents through other, unselected memory cells in the memory array. For example, the bit line BL is grounded (e.g., 0 V is supplied to the bit line BL) and an inhibition voltage is supplied to the write word line WWL. In some embodiments, a reference voltage other than 0 V is supplied to the bit line BL. A read voltage is supplied to the read word line RWL, turns ON the selector S2, and causes a read current Ir to flow along a read current path 131 from the read word line RWL, through the MTJ structure and the SOT layer to the bit line BL. A current value of the read current Ir corresponds to the datum stored in the MTJ structure. For example, when the MTJ structure is in the high resistance state corresponding to, e.g., logic “0”, the read current Ir has a smaller current value. When the MTJ structure is in the low resistance state corresponding to, e.g., logic “1”, the read current Ir has a higher current value. The sensing circuit 124 is electrically coupled to the bit line BL, e.g., through a corresponding conductor among the conductors Path0, Path1 to Pathm, and is configured to read the datum stored in the memory cell MC based on the sensed current value of the read current Ir. The above-described read operation is sometimes referred to as a random-access read operation in which a selected memory cell is accessed. An example CIM operation, in accordance with some embodiments, is a read operation in which multiple memory cells coupled to a bit line are accessed simultaneously.

In an example write “1” operation, i.e., a write operation for writing logic “1” into the memory cell MC, an inhibition bias is applied across the selector S2 to turn OFF the selector S2 and/or to suppress sneak currents through other, unselected memory cells in the memory array. For example, the bit line BL is grounded (e.g., 0 V is supplied to the bit line BL) and an inhibition voltage is supplied to the read word line RWL. In some embodiments, a reference voltage other than 0 V is supplied to the bit line BL. A write voltage is supplied to the write word line WWL, turns ON the selector S1, and causes a write current Iw1 to flow along a write current path 132 in a first direction from the write word line WWL, through the SOT layer, to the bit line BL. The write current Iw1 flowing through the SOT layer in the first direction causes the free layer in the MTJ structure to have a magnetization parallel to the magnetization of the reference layer, corresponding to logic “1” being written into the memory cell MC.

In an example write “0” operation, i.e., a write operation for writing logic “0” into the memory cell MC, an inhibition bias is applied across the selector S2 to turn OFF the selector S2 and/or to suppress sneak currents through other, unselected memory cells in the memory array. For example, the write word line WWL is grounded (e.g., 0 V is supplied to the write word line WWL) and an inhibition voltage is supplied to the read word line RWL. In some embodiments, a reference voltage other than 0 V is supplied to the write word line WWL. A write voltage is supplied to the bit line BL, turns ON the selector S1, and causes a write current Iw0 to flow along the write current path 132 in a second direction opposite to the first direction from the bit line BL, through the SOT layer, to the write word line WWL. The write current Iw0 flowing through the SOT layer in the second direction causes the free layer in the MTJ structure to have a magnetization anti-parallel to the magnetization of the reference layer, corresponding to logic “0” being written into the memory cell MC.

In some embodiments, the separate current paths for read operations and write operations, i.e., the read current path 131 and write current path 132, make it possible to tune the read resistance without affecting the write characteristics or write operation of the memory cell MC. Specifically, as described herein and further detailed with respect to FIG. 5A, a tunnel barrier layer is arranged in the MTJ structure and the read current Ir is caused to flow through the tunnel barrier layer. When a thickness of the tunnel barrier layer is increased, the resistance of the MTJ structure to the read current Ir, i.e., the read resistance, is increased. Conversely, when the thickness of the tunnel barrier layer is decreased, the read resistance, is decreased. Because the write current path 132 is different from the read current path 131, the write current Iw1 or Iw0 does not flow through the MTJ structure, and the thickness of the tunnel barrier layer does not affect the write characteristics or write operation of the memory cell MC, in one or more embodiments. In at least one embodiment, by configuring the thickness of the tunnel barrier layer in the MTJ structure, e.g., at the designing and/or manufacturing stage(s), it is possible to obtain one or more advantages. In an example, an increased thickness of the tunnel barrier layer reduces the read current Ir (at the same read voltage), lowers power consumption, and makes it possible to achieve low power CIM operations, in one or more embodiments. In a further example, memory cells in the memory arrays 101, 102, . . . 10J are formed with tunnel barrier layers having different thicknesses, resulting in corresponding different resistance-area products (RAs) for a multi-level cell configuration and/or different CIM functions, in one or more embodiments.

FIGS. 1B-1D are schematic circuit diagrams of a section of the memory device 100 in various operations, in accordance with some embodiments. The section of the memory device 100 in FIGS. 1B-1D is a portion of the memory array 101. In FIGS. 1B-1D, each memory cell of the memory array 101 is indicated by the bit line and the pair of word lines the memory cell is coupled to. For example, the memory cell coupled to the bit line BL0 and the pair of word lines RWL0, WWL0 is indicated as memory cell MC00, the memory cell coupled to the bit line BL0 and the pair of word lines RWL1, WWL1 is indicated as memory cell MC01, or the like. An example read operation is described with respect to FIG. 1B, an example write “1” operation is described with respect to FIG. 1C, and an example CIM operation is described with respect to FIG. 1D.

In FIG. 1B, the memory cell MC00 is selected to be accessed, i.e., read from, in an example read operation, in accordance with some embodiments. As described with respect to FIG. 1A, in a read operation for the selected memory cell MC00, the bit line BL0 is grounded, a read voltage V_{R} is supplied to the read word line RWL0, and an inhibition voltage is supplied to the write word line WWL0. The inhibition voltage is also supplied to other, unselected word lines and bit lines, which are not coupled to the selected memory cell MC00, to prevent other, unselected memory cells from being accidentally accessed and/or to suppress sneak currents through the other, unselected memory cells. In the example configuration in FIG. 1B, the inhibition voltage is V_{R}/2. In some embodiments, different inhibition voltages, e.g., αV_{R} and (1−α)V_{R} (where 0<α<1), are supplied to different unselected word lines and/or bit lines. Other values of the inhibition voltage are within the scopes of various embodiments. As described with respect to FIG. 1A, a read current Ir corresponding to the stored datum is output by the accessed memory cell MC00, resulting in a current I_{READ} flowing on the bit line BL0. In some embodiments, the current I_{READ} includes a sum of the read current Ir and one or more leakage currents. In at least one embodiment, the leakage currents are negligible. The conductor Path0 (not shown) couples the bit line BL0 to the sensing circuit 124 (not shown) which sensed the current I_{READ} to determine the datum stored in the memory cell MC00. Read operations are performed similarly in other memory arrays of the memory device 100. In some embodiments, different read operations are performed simultaneously or parallelly in different memory arrays of the memory array 101.

In FIG. 1C, the memory cell MC00 is selected to be accessed, i.e., written to, in an example write “1” operation, in accordance with some embodiments. As described with respect to FIG. 1A, in a write “1” operation for the selected memory cell MC00, the bit line BL0 is grounded, a write voltage V_{W} is supplied to the write word line WWL0, and an inhibition voltage V_{INH_RWL} is supplied to the read word line RWL0. Various inhibition voltages are also supplied to other, unselected word lines and bit lines, which are not coupled to the selected memory cell MC00, to prevent other, unselected memory cells from being accidentally accessed and/or to suppress sneak currents through the other, unselected memory cells. In the example configuration in FIG. 1C, the inhibition voltage V_{INH_RWL} is supplied to the read word lines, an inhibition voltage V_{INH_BL} is supplied to the unselected bit lines, and an inhibition voltage V_{INH_WWL} is supplied to the unselected write word lines. In at least one embodiment, V_{INH_BL}, V_{INH_RWL} and V_{INH_WWL} are all equal to V_{W}/2. In some embodiments, at least one of V_{INH_BL}, V_{INH_RWL} and V_{INH_WWL} is βV_{W} and at least another of V_{INH_BL}, V_{INH_RWL} and V_{INH_WWL} is (1−β)V_{W} (where 0<β<1). In at least one embodiment, V_{W} is equal to V_{R}. Other values of the inhibition voltages and/or V_{W} are within the scopes of various embodiments. As described with respect to FIG. 1A, a write current Iw1 is caused to flow through the SOT layer, and writes logic “1” into the MTJ structure of the memory cell MC00. The conductor Path0 (not shown) couples the bit line BL0 to the ground, e.g., in the sensing circuit 124 (not shown) or in a write circuit or a bit line driver of the memory controller 120. An example write “0” operation, in accordance with some embodiments, is similarly performed with a reversed direction of the write current, as described with respect to FIG. 1A. Write operations are performed similarly in other memory arrays of the memory device 100. In some embodiments, different write operations are performed simultaneously or parallelly in different memory arrays of the memory array 101.

In FIG. 1D, a CIM operation is performed by accessing one or more memory cells of the memory array 101. For example, all memory cells in the portion of the memory array 101 in FIG. 1D are accessed in a CIM operation, by supplying a read voltage V_{R} to the read word lines RWL0-RWL3, and grounding or supplying 0 V to the bit lines BL0-BL3 and the write word lines WWL0-WLL3. In some embodiments, a reference voltage other than 0 V is supplied to the bit lines BL0-BL3 and/or the write word lines WWL0-WLL3. In some embodiments, it is possible to exclude one or more memory cells from a CIM operation. For example, when the read word line RWL3 is grounded, the memory cells coupled to the read word line RWL3 are not accessed in a CIM operation. A CIM operation is similar to a read operation, with a difference in that multiple memory cells are accessed at the same time in the CIM operation. The selectors S1 of the memory cells are turned OFF, the selectors S2 of the accessed memory cells are turned ON, and a current similar to a read current is output by each of the accessed memory cells on the corresponding bit line. For example, the memory cell MC00 is caused to output a current I_{CIM00} on the corresponding bit line BL0. The current I_{CIM00} has a current value depending on a voltage value of V_{R}, and a conductance of the memory cell MC00. The conductance of the memory cell MC00 corresponds to the datum stored in the memory cell MC00. In some embodiments, the conductance of the memory cell MC00 also depends on the voltage value of V_{R} supplied to the corresponding read word line RWL0. In some embodiments, various values of conductance of a memory cell are predetermined, e.g., by calculation or simulation, for corresponding various combinations of a stored datum in the memory cell and a voltage value of V_{R} to be applied to the memory cell in a CIM operation.

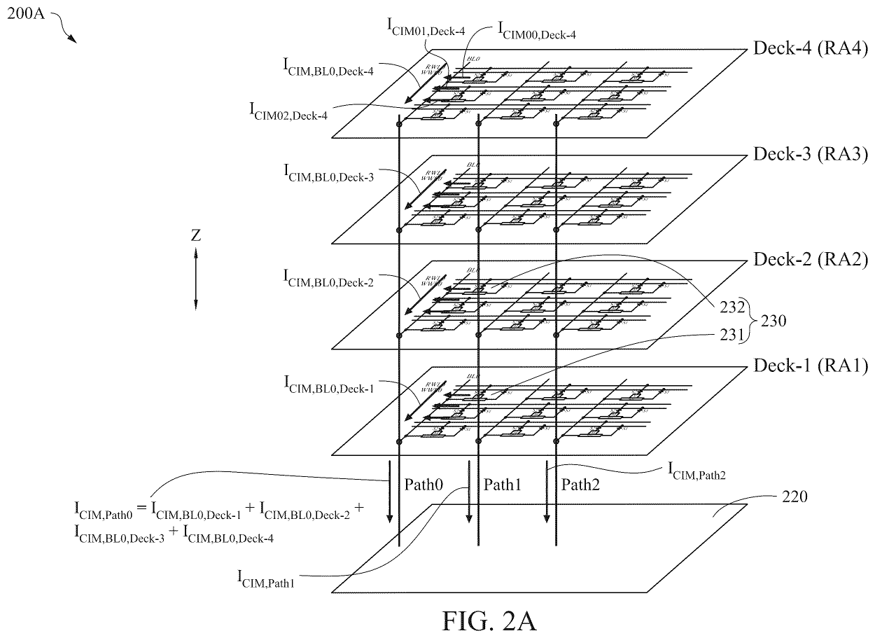

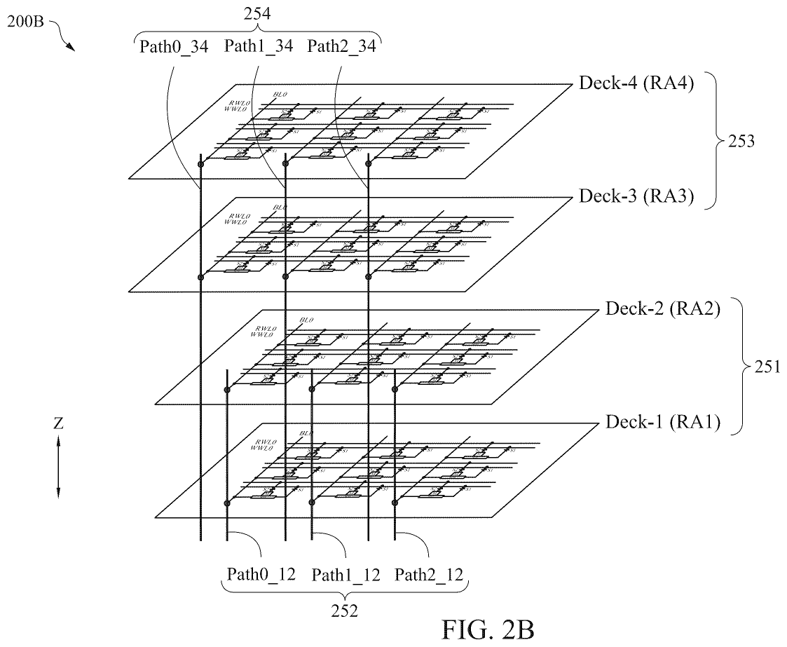

In a manner similar to that described with respect to the memory cell MC00, the memory cells MC01-MC03 are caused to output corresponding currents I_{CIM01}-I_{CIM03} on the bit line BL0. As a result, a bit line current I_{CIM,BL0}, which is collected on the bit line BL0, corresponds to a sum of currents I_{CIM00}-I_{CIM03} output by the memory cells MC00-MC03 in response to read voltages V_{R} which are input voltages supplied to the read word lines RWL0-RWL3. In FIG. 1D, the bit line current I_{CIM,BL0} is represented as I_{CIM,BL0}=ΣₙG_{n,0}(V_{R})·V_{R}, where G_{n,0}(V_{R}) represents the conductance of a corresponding memory cell coupled to the bit line BL0. As described herein, the conductance G_{n,0}(V_{R}) depends on the datum stored in the memory cell and a voltage value of V_{R}, in one or more embodiments. Similarly, bit line currents I_{CIM,BL1} to I_{CIM,BL3} are collected on the corresponding bit lines BL1-BL3. As described herein, e.g., with respect to FIG. 2A, the bit line currents I_{CIM,BL0} to I_{CIM,BL3} are further added to corresponding bit line currents from one or more other memory arrays of the memory device 100 in the same CIM operation.

In some embodiments, read voltages V_{R} supplied to the read word lines RWL0-RWL3 in a CIM operation correspond to input data, and are referred to as input voltages. In some embodiments, the input voltages supplied to the read word lines RWL0-RWL3 have the same voltage value. In at least one embodiment, the input voltages supplied to the read word lines RWL0-RWL3 have different voltage values. In some embodiments, the input voltages supplied to the read word lines RWL0-RWL3 are digital signals each having either a logic high level or a logic low level. In one or more embodiments, the input voltages supplied to the read word lines RWL0-RWL3 are analog voltages. In at least one embodiment, the set of bit line currents I_{CIM,BL0} to I_{CIM,BL3}, which are output by the accessed memory cells in response to the input voltages on the read word lines RWL0-RWL3 and collected on the corresponding bit lines BL0-BL3, represent a result of a computation involving the input data corresponding to the input voltages and the weight data stored in the accessed memory cells of the memory array 101.

In some embodiments, the input data correspond to an input vector, the weight data in the memory array 101 correspond to a weight matrix, and a computation involving the input data and the weight data corresponds to a matrix-vector multiplication (MVM). In some embodiments, write “1” operations and write “0” operations are performed to write or encode weight data into the memory array 101, e.g., in a training phase, read operations are performed to verify that the weight data have been correctly written, and CIM operations are performed to achieve a computation involving input data and the weight data written and/or verified in the memory array 101.

FIG. 2A is a schematic diagram of a memory device 200A, in accordance with some embodiments. In some embodiments, the memory device 200A corresponds to the memory device 100.

The memory device 200A comprises a plurality of memory arrays stacked one over another along a thickness direction of the memory device 200A. For example, the plurality of memory arrays in the memory device 200A are designated as Deck-1 to Deck-4 which are stacked one over another along a thickness direction, i.e., a Z direction, of the memory device 200A. Each of Deck-1 to Deck-4 comprises at least one bit line, and at least one memory cell coupled to the bit line. For example, each of Deck-1 to Deck-4 corresponds to a different memory array among the memory arrays 101, 102, . . . 10J, and comprises, as described with respect to FIG. 1A, bit lines such as BL0, BL1 or the like, word lines such as WWL0, RWL0, WWL1, RWL1 or the like, and memory cells coupled to corresponding bit lines and word lines.

Corresponding bit lines of at least two memory arrays among Deck-1 to Deck-4 are electrically coupled to each other. For example, corresponding bit lines BL0 of Deck-1 to Deck-4 are electrically coupled to each other by a conductor Path0, corresponding bit lines BL1 of Deck-1 to Deck-4 are electrically coupled to each other by a conductor Path1, corresponding bit lines BL2 of Deck-1 to Deck-4 are electrically coupled to each other by a conductor Path2, or the like, as described, e.g., with respect to FIG. 1A. In some embodiments, the corresponding bit lines of all memory arrays, or decks, in the memory device 200A are electrically coupled to each other. In at least one embodiment, the corresponding bit lines of fewer than all memory arrays, or decks, in the memory device 200A are electrically coupled to each other, for example, as described with respect to FIG. 2B.

The memory device 200A further comprises a memory controller 220. In some embodiments, the memory controller 220 corresponds to the memory controller 120, and is coupled to, and configured to control, Deck-1 to Deck-4 in a manner similar to the described manner in which the memory controller 120 is coupled to, and configured to control, the memory arrays 101, 102, . . . 10J. In the example configuration in FIG. 2A, the memory controller 220 is physically arranged below Deck-1 to Deck-4 along the Z direction, and is electrically coupled to the conductors Path0, Path1, Path2, or the like. Other physical arrangements of the memory controller 220 are within the scopes of various embodiments. In some embodiments, the memory controller 220 comprises, along the Z direction, a portion over Deck-4, and/or a portion at a same level as (e.g., co-elevational with) one or more of Deck-1 to Deck-4, and/or a portion between adjacent memory arrays among Deck-1 to Deck-4. The described number of stacked memory arrays, or decks, in the memory device 200A is an example. Other numbers of stacked memory arrays in a memory device are within the scopes of various embodiments.

In an example CIM operation in accordance with some embodiments, input voltages are supplied to read word lines in each of Deck-1 to Deck-4, whereas bit lines and write word lines in Deck-1 to Deck-4 are grounded. As described with respect to FIG. 1D, the input voltages cause corresponding accessed memory cells in each of Deck-1 to Deck-4 to output currents on the corresponding bit lines, and bit line currents are collected on the bit lines of Deck-1 to Deck-4. For example, as shown for Deck-4 in FIG. 2A, memory cells coupled to the bit line BL0 of Deck-4 output, in response to corresponding input voltages (not shown), currents I_{CIM00,Deck-4}, I_{CIM01,Deck-4}, I_{CIM02,Deck-4}, or the like. As a result, a bit line current I_{CIM,BL0,Deck-4} corresponding to a sum of I_{CIM00,Deck-4}, I_{CIM01,Deck-4}, I_{CIM02,Deck-4}, or the like, is collected on the bit line BL0 of Deck-4. Similarly, bit line currents I_{CIM,BL0,Deck-1}, I_{CIM,BL0,Deck-2}, I_{CIM,BL0,Deck-3}, are collected on corresponding bit lines BL0 of Deck-1, Deck-2, Deck-3. In some embodiments, the bit line currents I_{CIM,BL0,Deck-1}, I_{CIM,BL0,Deck-2}, I_{CIM,BL0,Deck-3}, I_{CIM,BL0,Deck-4} correspond to I_{CIM,BL0} described with respect to FIG. 1D. Because the bit lines BL0 of Deck-1 to Deck-4 are electrically coupled to each other by the conductor Path0, a path current I_{CIM,Path0} (sometimes referred to as CIM current) corresponding to a sum of I_{CIM,BL0,Deck-1}, I_{CIM,BL0,Deck-2}, I_{CIM,BL0,Deck-3}, I_{CIM,BL0,Deck-4} is collected on the conductor Path0. The path current I_{CIM,Path0} is supplied to the memory controller 220 which is configured to sense the path current and, based on the sensed path current, output a result of the CIM operation involving input data corresponding to the input voltages supplied to, and the weight data stored in, the accessed memory cells coupled to the bit lines BL0 of Deck-1 to Deck-4. Similarly, further path currents I_{CIM,Path1}, I_{CIM,Path2}, or the like, are correspondingly collected on the conductors Path1, Path2, or the like, and are supplied to and processed by the memory controller 220. A CIM operation involving bit line currents generated in two or more stacked memory arrays, as described, e.g., with respect to FIG. 2A, is sometimes referred to as a 3D CIM operation. A CIM operation involving bit line currents generated in a single memory array, as described, e.g., with respect to FIG. 1D, is sometimes referred to as a two-dimensional (2D) CIM operation.

In the above example, all of Deck-1 to Deck-4 are involved in a same CIM operation. Other configurations are within the scopes of various embodiments. In one or more embodiments, fewer than all of Deck-1 to Deck-4 are involved in a same CIM operation. For example, Deck-1 and Deck-2 are involved in a first CIM operation, and Deck-3 and Deck-4 are involved in a second CIM operation different or independent from the first CIM operation. In the first CIM operation, in accordance with some embodiments, input voltages corresponding to first input data are supplied to the read word lines of Deck-1 and Deck-2, whereas read word lines of Deck-3 and Deck-4 are grounded. As a result, bit line currents, e.g., I_{CIM,BL0,Deck-1}, I_{CIM,BL0,Deck-2}, in Deck-1 and Deck-2 are caused to flow to the corresponding conductors, e.g., conductor Path0, whereas bit line currents are not generated in Deck-3 and Deck-4. The path currents I_{CIM,Path0}, I_{CIM,Path1}, I_{CIM,Path2}, or the like, are sensed by the memory controller 220 to determine a result of the first CIM operation between the first input data and the weight data in Deck-1 and Deck-2. Similarly, in the second CIM operation, input voltages corresponding to second input data are supplied to the read word lines of Deck-3 and Deck-4, whereas read word lines of Deck-1 and Deck-2 are grounded. As a result, bit line currents, e.g., I_{CIM,BL0,Deck-3}, I_{CIM,BL0,Deck-4}, in Deck-3 and Deck-4 are caused to flow to the corresponding conductors, e.g., conductor Path0, whereas bit line currents are not generated in Deck-1 and Deck-2. The path currents I_{CIM,Path0}, I_{CIM,Path1}, I_{CIM,Path2}, or the like, are sensed by the memory controller 220 to determine a result of the second CIM operation between the second input data and the weight data in Deck-3 and Deck-4.

In some embodiments, the first CIM operation involving Deck-1, Deck-2 and the second CIM operation involving Deck-3, Deck-4 correspond to different first function and second function to be performed by the memory device 200A. Examples of functions to be performed by memory device 200A include, but are not limited to, artificial intelligence (AI), different layers of a neural network, classification of different features of a real-world object such as color, size, speed, weigh or the like, voice recognition, image recognition, image processing, telecommunication (e.g., in a switch), or the like. In some embodiments, the stacked memory arrays in a memory device are configured to perform more than two different functions or different CIM operations.

In at least one embodiment, the memory controller 220 is configured to controllably implement different configurations in which the stacked memory arrays are all used together for a same function or CIM operation, or are split into different sets of memory arrays for different functions or CIM operations. A first example configuration is described above, i.e., Deck-1 to Deck-4 are all used together for a single function. A second example is also described above, i.e., Deck-1 and Deck-2 form one set of memory arrays for one function, and Deck-3 and Deck-4 form another set of memory arrays for another function. In a third example configuration, Deck-1 and Deck-3 form one set of memory arrays for one function, and Deck-2 and Deck-4 form another set of memory arrays for another function. In a fourth example configuration, Deck-1, Deck-2 and Deck-3 form one set of memory arrays for one function, whereas Deck-4 forms another set (of one memory array) for another function (e.g., a 2D CIM operation). Other configurations are within the scopes of various embodiments. In some embodiments, the memory controller 220 is configured to switch, e.g., in response to user input, the stacked memory arrays between different configurations, which enhances functionality, flexibility, and/or adaptability of the memory device 200A for various applications. In some embodiments, a split of stacked memory arrays of a memory device into different sets of memory arrays for different functions is implemented by hard wiring, as described with respect to FIG. 2B, instead of or in addition to using a memory controller.

In some embodiments, resistance-area product (RA) is a feature to be considered for one or more of Deck-1 to Deck-4. In at least one embodiment, all memory cells in a memory array have the same configuration, and an RA of a memory cell in the memory array represents an RA of the memory array. Generally, RA is calculated by multiplying a structure's resistance by an area of the structure, and corresponds to a combined effect of both the resistance and the area through which current flows. For a memory cell having the memory cell configuration 130 or another memory cell configuration including an MTJ structure, an RA of the memory cell is calculated by multiplying a low resistance Rp of the memory cell (e.g., when the magnetizations of the free layer and the reference layer are parallel in the P state, or when the memory cell stores logic “1”) by an area of the MTJ structure in the memory cell, i.e., RA=Rp×MTJ area. At a given MTJ area, RA corresponds to Rp. In some embodiments, an RA of a memory cell corresponds to the conductance of the memory cell, as described with respect to FIG. 1D.

In some embodiments, memory window is a further feature to be considered for one or more of Deck-1 to Deck-4. In at least one embodiment, all memory cells in a memory array have the same configuration, and a memory window of a memory cell in the memory array represents a memory window of the memory array. A ratio between a high resistance Rap of the memory cell (e.g., when the magnetizations of the free layer and the reference layer are anti-parallel in the AP state, or when the memory cell stores logic “0”) and the memory cell's low resistance Rp is sometimes referred to as a memory window of the of the memory cell, i.e., memory window is determined as Rap/Rp. Sometimes, memory window is determined as (Rap−Rp)/Rp. For simplicity, in examples discussed hereinafter, memory window is determined as Rap/Rp. A memory cell has a resistance range from Rp (corresponding to RA) in the P state to Rap (corresponding to RA×memory window) in the AP state. For example, a memory cell has an RA of 1 kΩ·μm², a memory window of 4:1, and a resistance range corresponding to 1 kΩ·μm² to 4 kΩ·μm².

In some embodiments, the RA of a memory cell depends on a thickness of the tunnel barrier layer, whereas the memory window of the memory cell depends on a material of the tunnel barrier layer. A higher memory window ensures more reliable data storage or retention, in one or more embodiments. In some embodiments, the memory window determines the programmable resistance values (i.e., Rp and Rap) for a given memory array with a given MTJ structure, e.g., with a given thickness of the tunnel barrier layer.

In some embodiments, the RA of a memory array is tunable within a range, referred to herein as RA range, by configuring the tunnel barrier layer to have an appropriate thickness. In at least one embodiment, a greater thickness of the tunnel barrier layer results in a higher RA. A higher RA lowers power consumption, and is suitable for low power CIM operations, in one or more embodiments. In at least one embodiment, a smaller thickness of the tunnel barrier layer results in a lower RA. Generally, a lower RA increases switching speed, i.e., enhances performance, in one or more embodiments. For example, in a SOT MRAM memory cell in accordance with some embodiments, a lower RA increases the read speed, i.e., enhances the read performance. In some embodiments, as described herein, a wide RA range is possible in different memory arrays thanks to tunability of the thickness of the tunnel barrier layer. In one or more embodiments, as described herein, SOT MRAM memory cells or memory arrays comprise MgO as the tunnel barrier layer, and a very large RA range, e.g., of several orders of magnitude, is achievable by tuning the MgO thickness, while the memory window remains substantially unchanged.

In at least one embodiment, at the designing and/or manufacturing stage(s), by selecting an appropriate material for the tunnel barrier layer, it is possible to achieve an intended memory window for data reliability, whereas by simply selecting an appropriate thickness of the tunnel barrier layer, it is possible to achieve an intended RA that provides a balance among various considerations, such as, power consumption, performance, or the like.

In the example configuration in FIG. 2A, Deck-1 to Deck-4 correspondingly have different RAs, namely, RA1-RA4. In at least one embodiment, the tunnel barrier layers in Deck-1 to Deck-4 have the same material corresponding to the same memory window, but Deck-1 to Deck-4 correspondingly have different thicknesses. For example, the tunnel barrier layer in Deck-1 has the thinnest thickness, the tunnel barrier layer in Deck-2 has a thickness greater than the thickness of the tunnel barrier layer in Deck-1, the tunnel barrier layer in Deck-3 has a thickness greater than the thickness of the tunnel barrier layer in Deck-2, the tunnel barrier layer in Deck-4 has a thickness greater than the thickness of the tunnel barrier layer in Deck-3, or the like. As a result, RA1<RA2<RA3<RA4. In some embodiments, RA1-RA4 are different from each other by multiples of a predetermined number. For example, for the predetermined number being 2, RA4=2×RA3, RA3=2×RA2, RA2=2×RA1. Other RA distribution are within the scopes of various embodiments.

In a CIM operation, because RA1<RA2<RA3<RA4, maximal currents output by Deck-1 are greater than maximal currents output by accessed memory cells in Deck-2, which in turn are greater than maximal currents output by accessed memory cells in Deck-3, which in turn are greater than maximal currents output by accessed memory cells in Deck-4, or the like. For example, I_{CIM,BL0,Deck-4} is up to 1 μA, I_{CIM,BL0,Deck-3} is up to 10 μA, I_{CIM,BL0,Deck-2} is up to 100 μA, I_{CIM,BL0,Deck-1} is up to 1000 μA (or 1 mA). Other current distribution are within the scopes of various embodiments. In some embodiments, the described cascading distribution of I_{CIM,BL0,Deck-1} to I_{CIM,BL0,Deck-4} makes it possible to simplify the determination of a result of the CIM operation based on the sensed path current I_{CIM,Path0}. In some embodiments, RA1-RA4 of Deck-1 to Deck-4, or coefficients corresponding to RA1-RA4, are predetermined and stored, e.g., in a storage circuit of the memory controller 220. The memory controller 220 is configured to use the stored RA1-RA4, or the stored coefficients corresponding RA1-RA4, to determine results of CIM operations based on sensed path currents. In some embodiments, the deck with the lowest RA, e.g., Deck-1 with RA1, is configured to store the most significant bit (MSB) weight data. Deck-2 with RA2>RA1 is configured to store weight data of lower significance than the MSB weight data in Deck-1. Deck-3 with RA3>RA2 is configured to store weight data of lower significance than the weight data in Deck-2. Deck-4 with the highest RA4 is configured to encode the least significant bit (LSB) weight data.

As described herein, a SOT MRAM memory cell has separate read current path and write current path. In some embodiments, this configuration enables conductance or RA of the SOT MRAM memory cell to be tunable, at the designing and/or manufacturing stage(s), over a wide RA range, without affecting write characteristics, such as write voltage and/or write energy, and/or without stability issues. In at least one embodiment, it is possible to tune the RA of a SOT MRAM memory cell over a wide RA range, e.g., from 10 times to 1000 times, by configuring the tunnel barrier layer, e.g., a MgO layer, to have an appropriate thickness. This wide RA range is used for RA distribution among the decks, in one or more embodiments. For example, Deck-1 is configured to have an RA of 1 kΩ·μm², a memory window of 4:1, and a resistance range corresponding to 1 kΩ·μm² to 4 kΩ·μm². Deck-2 is configured to have an RA of 10 kΩ·μm², the same memory window of 4:1, and a resistance range corresponding to 10 kΩ·μm² to 40 kΩ·μm². Deck-3 is configured to have an RA of 100 kΩ·μm², the same memory window of 4:1, and a resistance range corresponding to 100 kΩ·μm² to 400 kΩ·μm². Deck-4 is configured to have an RA of 1 MΩ·μm², the same memory window of 4:1, and a resistance range corresponding to 1 MΩ·μm² to 4 MΩ·μm². Thus, the RAs in Deck-1 to Deck-4 vary 1000 times from Deck-1 (1 kΩ·μm²) to Deck-4 (1 MΩ·μm²). In some embodiments, the great difference (e.g., 10 times) between the RAs of successive decks (e.g., between Deck-1 and Deck-2) results in a corresponding large difference between bit line currents the successive decks output to a common path current, which makes it possible to simplify the determination of a result of a CIM operation based on the path current. The described specific RAs, and/or number of decks, and/or differences between RAs of successive decks are examples. Other configurations are within the scopes of various embodiments. For example, the RA of a memory cell is tunable via the thickness of the MgO layer in the RA range of 10~10000 Ω·μm², in one or more embodiments. In some embodiments, high RA memory arrays make it possible to achieve low-current and/or low-power CIM operations. The described RA tunability over a wide RA range is an improvement of SOT MRAM over other memory technologies, such as RRAM or PCM, although the other memory technologies are still usable in one or more decks of memory cells of a memory device, in one or more embodiments.

The described configuration in which all of Deck-1 to Deck-4 have different RAs and/or different tunnel barrier layer thicknesses is an example. Other configurations are within the scopes of various embodiments. In some embodiments, two of more of Deck-1 to Deck-4 have a same RA and/or a same tunnel barrier layer thickness. In at least one embodiment, all of Deck-1 to Deck-4 have the same RA and/or tunnel barrier layer thickness. In some embodiments, two of more of Deck-1 to Deck-4 have different RAs and/or tunnel barrier layer thicknesses.

In some embodiments, memory cells of different decks are combined to implement an equivalent memory cell with multi-level conductance. A memory cell with multi-level conductance, or multi-level memory cell, has multiple conductance levels higher than a low conductance level (or high resistance state). An MRAM memory cell, such as a memory cell having the memory cell configuration 130, has one conductance level (or low resistance state) higher than the low conductance level (or high resistance state), and is considered as a memory cell with single-level conductance, or binary memory cell. A memory cell in accordance with other memory technologies, e.g., RRAM or PCM, is configured to have at least one intermediate conductance level (or intermediate state) between a high conductance level and a low conductance level. Such RRAM or PCM memory cell has two or more conductance levels higher than the low conductance level, is considered as a memory cell with multi-level conductance. A memory cell with multi-level conductance advantageously increases the amount of data to be stored or processed. However, in certain situations, the intermediate state is potentially unstable, with further potential issues related to data reliability and/or calculation accuracy.

In some embodiments, two memory cells with single-level conductance of different decks are combined to implement an equivalent memory cell with multi-level conductance. For example, two stacked memory cells MC00 of Deck-1 and Deck-2, correspondingly designated as memory cells 231, 232, are combinable to form an equivalent memory cell 230 with multi-level conductance. The equivalent memory cell 230 has a low conductance level corresponding to both the memory cells 231, 232 having a low conductance level, e.g., when both the memory cells 231, 232 store logic “0”. The equivalent memory cell 230 has a high conductance level corresponding to both the memory cells 231, 232 having a high conductance level, e.g., when both the memory cells 231, 232 store logic “1”. The equivalent memory cell 230 has at least one intermediate conductance level (or intermediate state) when one of the memory cells 231, 232 has the low conductance level (e.g., one memory cell stores logic “0”) and the other of the memory cells 231, 232 has the high conductance level (e.g., the other memory cell stores logic “1”). In some embodiments where RA1=RA2 and in a CIM operation where currents output by the memory cells 231, 232 are merged into the path current I_{CIM,Path0}, there is no discernable difference in the path current I_{CIM,Path0}, i.e., in the conductance level of the equivalent memory cell 230, between when the memory cell 231 stores logic “0” and the memory cell 232 stores logic “1”, and when the memory cell 231 stores logic “1” and the memory cell 232 stores logic “0”. In such situations, the equivalent memory cell 230 is considered to have one intermediate conductance level. In some embodiments where RA1 is different from RA2, e.g., RA1<RA2, the conductance level of the equivalent memory cell 230 when the memory cell 231 stores logic “1” and the memory cell 232 stores logic “0” is different from (e.g., higher than) when the memory cell 231 stores logic “0” and the memory cell 232 stores logic “1”. In such situations, the equivalent memory cell 230 is considered to have two intermediate conductance levels. Other numbers of memory cells being combinable into an equivalent memory cell with multi-level conductance and/or other RA distributions in such equivalent memory cell are within the scopes of various embodiments.

As discussed herein, an intermediate state of a RRAM or PCM memory cell is potentially unstable. In contrast, an intermediate state of an equivalent memory cell in accordance with some embodiments, e.g., the equivalent memory cell 230, is configured by stable states (i.e., logic “0” or logic “1”) of multiple MRAM memory cells, and is also stable. As a result, it is possible in one or more embodiments to achieve the advantage of RRAM or PCM memory cells with multi-level conductance, while avoiding their potential instability issues.

In at least one embodiment, a combination of memory cells of different decks into an equivalent memory cell with multi-level conductance is implementable without additional wiring among the memory cells or the decks. For example, in a CIM operation, the memory controller 220 is configured to supply the same input voltage to the read word lines of the memory cells 231, 232. This CIM operation corresponds to the input data represented by the input voltage being computed, e.g., multiplied, with the weight data stored in the equivalent memory cell 230.

Further implementations of a memory device with multiple decks of memory cells are within the scopes of various embodiments. In some embodiments, at least two, or all, of the decks are different from each other in at least one of memory cell configuration, memory technology, material and/or thickness of one or more conductance controlling layers that control conductance (or resistance) of memory cells, or the like. Non-limiting examples of different memory cell configurations are described with respect to FIGS. 5A-5D, 6A-6B. Non-limiting examples of different memory technologies include, but are not limited to, SOT MRAM, STT MRAM, RRAM, PCM, FeRAM, ECRAM, or the like. In some embodiments, conductance controlling layers that control conductance (or resistance) of memory cells are those configured to pass therethrough a current in a read operation or a CIM operation of the memory cells. Non-limiting examples of such layers and corresponding example materials are described with respect to FIGS. 5A-5D, 6A-6B.

In some embodiments, by configuring different decks of a memory device with different memory technologies, or with the same memory technology but with different memory cell configurations, materials and/or thicknesses of conductance controlling layers, it is possible to implement different CIM functions and/or to cover different conductance ranges and/or to optimize different conductance multi-levels, with one or more advantages as described herein. For example, a first memory technology is suitable to or optimized for a first CIM function, and a different, second memory technology is suitable to or optimized for a second CIM function different from the first CIM function. In at least one embodiment, one or more first memory arrays among the stacked memory arrays are formed with the first memory technology to perform the first CIM function, and one or more further, second memory arrays among the stacked memory arrays are formed with the second memory technology to perform the second CIM function.

In some embodiments, multiple 2D memory arrays, or decks, of a memory device are stacked along a thickness direction into a 3D structure, by employing back-end-of-line (BEOL) compatible circuit elements, such as selectors, and memory technologies. For a CIM operation in such a 3D structure, the summed current (e.g., bit line current) of each deck corresponds to 2D CIM (or MVM) result in that deck, and is collected by a vertical path, conductor, or interconnect, to perform current summation in the thickness direction of the memory device. As a result, a 3D CIM (or MVM) result is obtained. In at least one embodiment, a high-density and 3D-stackable CIM system is achievable due to BEOL-compatible memory technologies.

In some embodiments, memory cells of different decks are combinable to encode multiple conductance levels, for example by using memory technologies with high conductance stability (e.g., STT MRAM, SOT MRAM, or the like). In at least one embodiment, such combination of memory cells in the vertical direction (or thickness direction) does not degrade the area efficiency. In one or more embodiments, each deck is configured to have a different RA to optimize the multiple conductance levels.

In some embodiments, all decks of the memory device are parts of a BEOL structure, are formed over, and do not occupy chip areas of, a substrate on which front-end-of-line (FEOL) circuitry is formed. As a result, additional chip areas are freed up for the FEOL circuitry, such as the memory controller 220. This is an improvement over other approaches with FEOL memory arrays. In at least one embodiment, the physically lowest deck, e.g., Deck-1 in FIG. 2A, is implemented as FEOL circuitry, yet one or more of the described advantages are still obtainable, thanks to the 3D structure of stacked decks and/or the other decks being formed as parts of a BEOL structure.

FIG. 2B is a schematic diagrams of a memory device 200B, in accordance with some embodiments. In some embodiments, the memory device 200B corresponds to one or more of the memory devices 100, 200A. Components in FIG. 2B having corresponding components in FIG. 2A are designated by the same reference numerals as in FIG. 2A. The memory device 200B comprises memory arrays Deck-1 to Deck-4 and a memory controller, as in the memory device 200A. For simplicity, the memory controller of the memory device 200B is omitted in FIG. 2B.

Compared to the memory device 200A in which a split of the stacked memory arrays, i.e., Deck-1 to Deck-4, of the memory device 200A into different sets of memory arrays for different functions or CIM operations is implemented by software or control of the memory controller 220, such a split in the memory device 200B is implemented by hard wiring. For example, corresponding bit lines of a first memory array set 251 including Deck-1 and Deck-2 are coupled to each other by a first conductor set 252 of conductors Path0_12, Path1_12, Path2_12, or the like, whereas corresponding bit lines of a second memory array set 253 including Deck-3 and Deck-4 are coupled to each other by a second conductor set 254 of conductors Path0_34, Path1_34, Path2_34, or the like. In at least one embodiment, the bit lines of Deck-1 and Deck-2 are not electrically coupled to the corresponding bit lines and the second conductor set 254 of Deck-3 and Deck-4. Likewise, the bit lines of Deck-3 and Deck-4 are not electrically coupled to the corresponding bit lines and the first conductor set 252 of Deck-1 and Deck-2. In some embodiments, the first conductor set 252 and second conductor set 254 are coupled to different sensing circuits and/or bit line drivers in access operations, e.g., write operations, read operations, and/or CIM operations, of the first memory array set 251 and second memory array set 253. In at least one embodiment, the separation of conductor sets, sensing circuits and/or bit line drivers between the first memory array set 251 and second memory array set 253 permits access operations of the first memory array set 251 to be performed independently from access operations of the second memory array set 253. In at least one embodiment, the first conductor set 252 and second conductor set 254 are coupled to a same sensing circuit and/or a same bit line driver, e.g., through a bit line selection circuit. One or more advantages described herein with respect to the memory devices 100, 200A are achievable by the memory device 200B, in accordance with some embodiments.

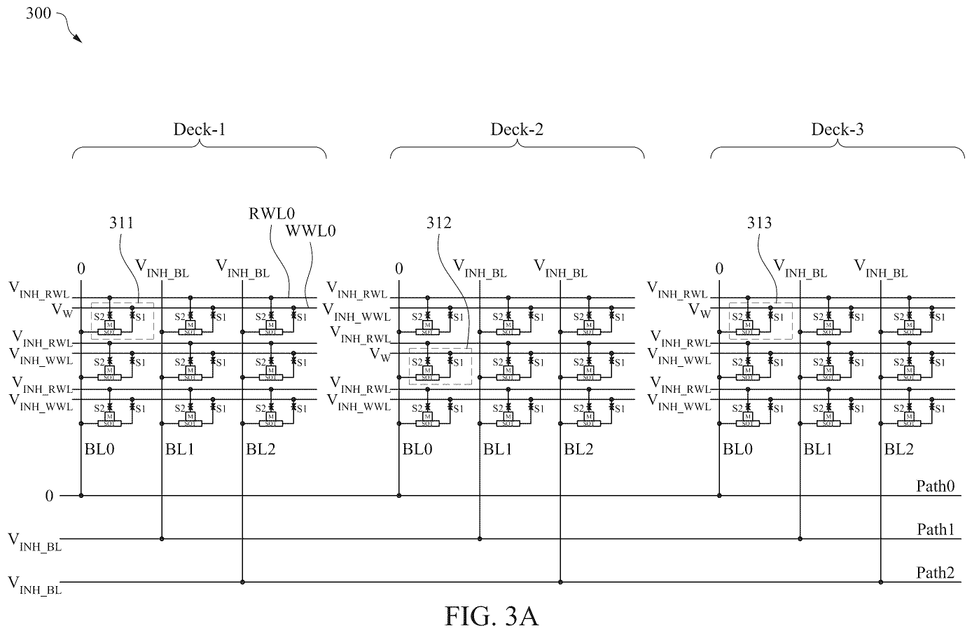

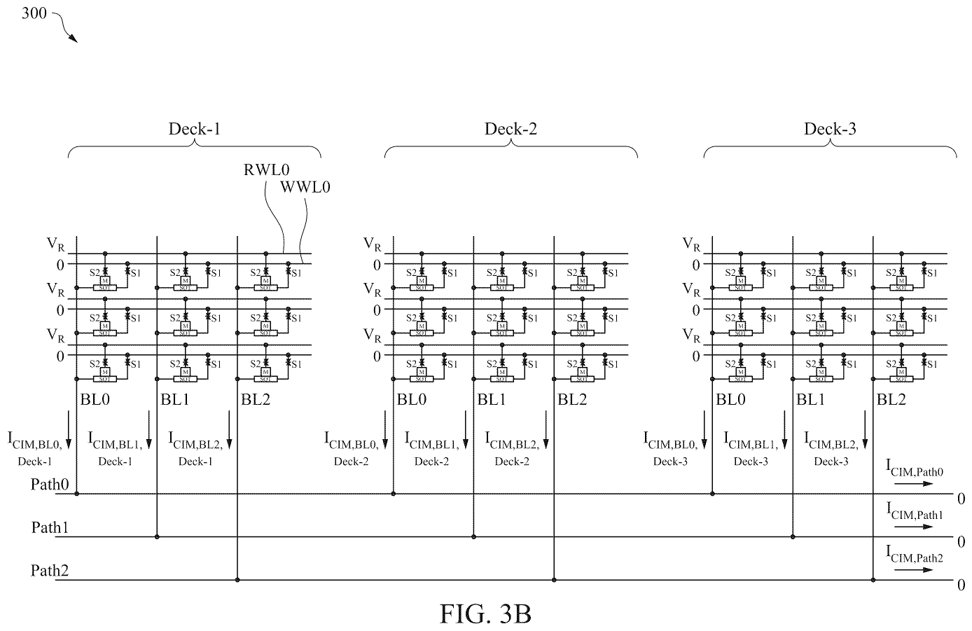

FIG. 3A-3B are schematic circuit diagrams of a section of a memory device 300 in various operations, in accordance with some embodiments. In some embodiments, the memory device 300 corresponds to one or more of the memory devices 100, 200A, 200B. Components in FIGS. 3A-3B having corresponding components in FIG. 2A are designated by the same reference numerals as in FIG. 2A. In FIGS. 3A-3B, for each memory cell, the read word line is illustrated above the corresponding write word line, for example, as indicated at read word line RWL0 and write word line WWL0 for a memory cell 311 in Deck-1. Other read word lines and write word lines are not labeled for simplicity. An example write “1” operation is described with respect to FIG. 3A, and an example CIM operation is described with respect to FIG. 3B.

In FIG. 3A, a write “1” operation, in accordance with some embodiments, is performed simultaneously for selected memory cells 311, 312, 313 correspondingly in Deck-1, Deck-2, Deck-3. For each of the Deck-1 to Deck-3, the write “1” operation of the corresponding selected memory cell is similar to that described with respect to FIG. 1C. Specifically, a write voltage V_{W} is supplied to the selected write word lines coupled to the selected memory cells 311, 312, 313, whereas an inhibition voltage V_{INH_WWL} is supplied to the unselected write word lines in Deck-1 to Deck-3. An inhibition voltage V_{INH_RWL} is supplied to all the read word lines in Deck-1 to Deck-3. The selected bit lines BL0 coupled to the selected memory cells 311, 312, 313 are grounded through the corresponding conductor Path0 to which a zero voltage (0 V) is supplied, whereas an inhibition voltage V_{INH_BL} is supplied to the unselected bit lines in Deck-1 to Deck-3, through the corresponding unselected conductors Path1, Path 2.

An example write “0” operation, in accordance with some embodiments, is similarly performed with a reversed direction of the write current, as described with respect to FIG. 1A. In at least one embodiment, a write “1” operation and a write “0” operation are performed at the same time. For example, a write “1” operation is performed for selected memory cells coupled to conductor Path0 through the bit lines BL0, and simultaneously, a write “0” operation is performed for selected memory cells coupled to conductor Path1 through the bit lines BL1. The described write operations are examples of parallel training or encoding of weight data in multiple stacked memory arrays of a memory device, in accordance with some embodiments.

In FIG. 3B, a CIM operation, in accordance with some embodiments, is performed in a manner similar to that described with respect to FIG. 1D. Specifically, input voltages schematically indicated as read voltages V_{R} are supplied to the read word lines in Deck-1 to Deck-3, whereas the write word lines in Deck-1 to Deck-3 are grounded. Further, the bit lines in Deck-1 to Deck-3 are grounded through the corresponding conductors Path0, Path1, Path2, or the like. Voltage values of the input voltages applied to the read word lines are not necessarily the same, but are potentially different from each other depending on the input data to be computed with the weight data in this CIM operation. In response to the input voltages, the memory cells in Deck-1 to Deck-3 output corresponding currents to the corresponding bit lines, resulting in bit line currents I_{CIM,BL0,Deck-1}, I_{CIM,BL1,Deck-1}, I_{CIM,BL2,Deck-1} from Deck-1, bit line currents I_{CIM,BL0,Deck-2}, I_{CIM,BL1,Deck-2}, I_{CIM,BL2,Deck-2} from Deck-2, bit line currents I_{CIM,BL0,Deck-3}, I_{CIM,BL1,Deck-3}, I_{CIM,BL2,Deck-3} from Deck-3. The bit line currents are collected on the corresponding conductors Path0, Path1, Path2, resulting in path currents I_{CIM,Path0}, I_{CIM,Path1}, I_{CIM,Path2} flowing to a sensing circuit (not shown). The path currents are sensed and, based on the sensed path currents, a result of the CIM operation involving the input data and the weight data stored in Deck-1 to Deck-3 is determined. One or more advantages described herein are achievable by the memory device 300, in accordance with some embodiments.

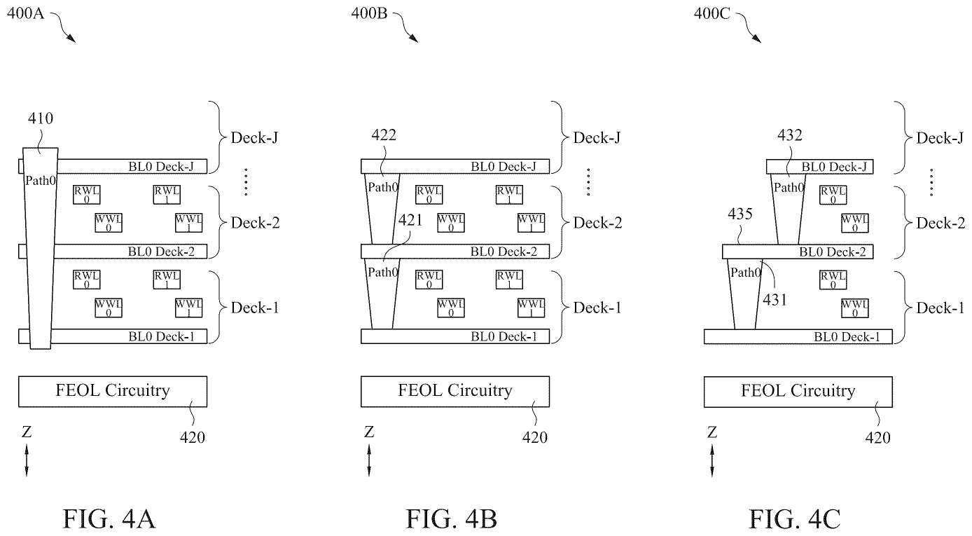

FIGS. 4A, 4B, 4C are schematic cross-sectional views of portions of corresponding memory devices 400A, 400B, 400C, in accordance with some embodiments. In some embodiments, one or more of the memory devices 400A-400C correspond to one or more of the memory devices 100, 200A, 200B, 300. Components in FIGS. 4A-4C having corresponding components in FIG. 2A are designated by the same reference numerals as in FIG. 2A.

In each of FIGS. 4A-4C, the corresponding memory device 400A, 400B, 400C comprises a plurality of memory arrays, i.e., Deck-1, Deck-2 to Deck-J stacked one over another along a thickness direction Z of the memory device. Deck-1, Deck-2 to Deck-J are parts of a BEOL structure formed over FEOL circuitry 420 of the memory device. In some embodiments, the Deck-1, Deck-2 to Deck-J correspond to memory arrays 101, 102, . . . 10J in FIG. 1A, and/or Deck-1 to Deck-4 in FIG. 2A. In at least one embodiment, the FEOL circuitry 420 comprises a memory controller corresponding to the memory controller 120 and/or memory controller 220. Details of example FEOL circuitry are described with respect to FIG. 6B. For simplicity not all memory arrays, or decks, are illustrated in FIGS. 4A-4C. Further, each of the illustrated decks, i.e., Deck-1 and Deck-2, is schematically represented by corresponding bit lines BL0, read word lines RWL0, RWL1, and write word lines WWL0, WWL1, whereas other features such as selectors, MTJ structures, SOT layers are omitted. Examples of such features are described with respect to FIG. 5A. Structures that couple the bit lines BL0 of the stacked decks in each of the memory devices 400A, 400B, 400C are described herein. Other bit lines (not shown) of the stacked decks are coupled in a similar manner.

In FIG. 4A, the bit lines BL0 of Deck-1, Deck-2 to Deck-J of the memory device 400A are electrically coupled to each other by a conductor 410 corresponding to the conductor Path0. In the example configuration in FIG. 4A, the conductor 410 comprises a via structure extending along the thickness direction Z, from the bit line BL0 of Deck-J, through the bit lines BL0 of the decks below Deck-J, to the bit line BL0 of Deck-1. In some embodiments, the conductor 410 extends to the FEOL circuitry 420 to make electrical contact with the FEOL circuitry 420. In some embodiments, the conductor 410 or the bit line BL0 of Deck-1 is electrically coupled to the FEOL circuitry 420 by an interconnect comprising one or more metal patterns and one or more vias, as described with respect to FIG. 6B. In at least one embodiment, after sequentially forming Deck-1, Deck-2, Deck-(J-1) (not shown), and the bit line BL0 of Deck-J over the FEOL circuitry 420, the conductor 410 is formed by etching a via hole extending through the bit line BL0 of Deck-J and Deck-1, Deck-2, Deck-(J-1), and filling the via hole with a conductive material. In some embodiments, the conductor 410 is formed in whole or in part by one or more interconnects each comprising one or more metal patterns and one or more vias. Other configurations and/or manufacturing processes of the conductor 410 are within the scopes of various embodiments.

In FIG. 4B, the memory device 400B comprises a different configuration for conductor Path0, compared to the memory device 400A. Specifically, instead of a single conductor 410, the memory device 400B comprises multiple conductors 421, 422. The conductors 421, 422 overlap each other along the thickness direction Z. In some embodiments, a vertical centerline of the conductor 421 is aligned, or coincides, with a vertical centerline of the conductor 422. In the example configuration in FIG. 4B, the conductor 421 comprises a first via structure extending along the thickness direction Z, and electrically coupling the bit lines BL0 of a first set of memory arrays, e.g., Deck-1 and Deck-2. The conductor 422 comprises a second via structure extending along the thickness direction Z, and electrically coupling the bit lines BL0 of a second set of memory arrays, e.g., Deck-2 and one or more decks above Deck-2. In this example, Deck-2 is a common memory array shared by the first set of memory arrays and the second set of memory arrays. The bit line BL0 of Deck-2 is between and couples the first via structure, i.e., the conductor 421, and the second via structure, i.e., the conductor 422. In some embodiments, a via structure like the conductor 421 is formed for each deck, and is arranged between and couples the bit line BL0 of the corresponding deck with the bit line BL0 of the immediately above deck. In at least one embodiment, the configuration of conductor Path0 as comprising multiple conductors enhances manufacturability, especially where formation of a single deep via structure is difficult or complex. In some embodiments, at least one of the conductors 421, 422 is formed in whole or in part by one or more interconnects each comprising one or more metal patterns and one or more vias. Other configurations and/or manufacturing processes of the conductors 421, 422 are within the scopes of various embodiments.

In FIG. 4C, the memory device 400C comprises a different arrangement of multiple conductors forming the conductor Path0, compared to the memory device 400B. Specifically, the memory device 400C comprises multiple conductors 431, 432 corresponding to the conductors 421, 422 in the memory device 400B. However, unlike the conductors 421, 422 which overlap each other along the thickness direction Z, conductors 431, 432 do not overlap each other along the thickness direction Z. In this arrangement, a portion 435 over at least one of the conductors, e.g., over the conductor 431, is freed up for other electrical connections. One or more advantages described herein are achievable by one or more of the memory devices 400A, 400B, 400C, in accordance with some embodiments.

FIG. 5A includes a schematic circuit diagram, a perspective view and a cross-sectional view of a memory cell 500A, in accordance with some embodiments. In some embodiments, the memory cell 500A corresponds to a memory cell in one or more memory arrays of one or more of the memory devices 100, 200A, 200B, 300, 400A-400C.

As shown in the schematic circuit diagram in FIG. 5A, the memory cell 500A has the memory cell configuration 130 with two selectors S1, S2, and an MTJ structure with a SOT layer. The memory cell configuration 130 is sometimes referred to as 2S-1SOT MRAM.

As shown in the perspective view in FIG. 5A, the memory cell 500A, each of the selectors S1, S2 and the MTJ structure comprises a multilayer structure details of which are described with respect to the cross-sectional view of the memory cell 500A. A read word line 501 is over and in electrical contact with a top layer of the selector S2. The read word line 501 is a metal pattern in a metal layer as described herein, and is elongated along a Y direction transverse to the Z direction. The selector S2 is over the MTJ structure, with a bottom layer of the selector S2 in electrical contact with a top layer of the MTJ structure. The MTJ structure is over the SOT layer 504 which is elongated along an X direction transverse to both the Y direction and the Z direction. A first end of the SOT layer 504 is over and in electrical contact with a top layer of the selector S1. A bottom layer of the selector S1 is over and in electrical contact with a write word line 502. The write word line 502 is a metal pattern in a metal layer, and is elongated along the Y direction. A second end of the SOT layer 504 is over and in electrical contact with an interconnect 505. In the example configuration in FIG. 5A, the interconnect 505 comprises a via 506, a metal pattern 507, and another via 508. The via 508 is over and in electrical contact with a bit line 503 which is a metal pattern in a metal layer, and is elongated along the Z direction. The metal pattern 507 is over and in electrical contact with the via 508. In some embodiments, the metal pattern 507 is in the same metal layer as the write word line 502. The via 506 is over and in electrical contact with the 507, and is under and in electrical contact with the SOT layer 504.

As shown in the cross-sectional view in FIG. 5A, the selector S1 comprises a first electrode 511 as the top layer, a second electrode 513 as the bottom layer, and a switching layer 512 between the first electrode 511 and second electrode 513. The selector S2 comprises a first electrode 514 as the top layer, a second electrode 516 as the bottom layer, and a switching layer 515 between the first electrode 514 and second electrode 516. Example materials of the electrodes 511, 513, 514, 516 include, but are not limited to, W, TiN, TaN, C, SiC, or the like. Example materials of the switching layers 512, 515 include, but are not limited to, SiNGeCTe, NGeCTe, GeCTe, SiGeAsTe, AsGeSe, SiAsGeSe, or the like. In some embodiments, the switching layers 512, 515 have different materials and/or thicknesses to independently tune the switching characteristics (e.g., threshold voltages) of the selector S1 and selector S2 in accordance with the intended functionality.

The MTJ structure comprises a reference layer (or fixed layer) 517 as the top layer, a free layer 519 as a bottom layer, and a tunnel barrier layer 518 between the reference layer 517 and free layer 519. In some embodiments, the MTJ structure further comprises pinning and coupling layers on top of the reference layer 517. In an example configuration in accordance with some embodiments, the reference layer 517 comprises CoFeB, the tunnel barrier layer 518 comprises MgO, and the free layer 519 comprises CoFeB. Example materials of the SOT layer 504 include, but are not limited to, W, doped-W, Pt, Ta, 2D materials such as BeSe2, or the like. Other materials are within the scopes of various embodiments.

The physical arrangement of various layers of the memory cell 500A as illustrated in FIG. 5A is an example. Other physical arrangement of various layers in the memory cell 500A are within the scopes of various embodiments. For example, in one or more embodiments, the selector S1 and selector S2 are at the same level, so that one electrode of the selector S1 and one electrode of the selector S2 are manufactured at the same time, the switching layers 512, 515 are manufactured at the same time, and the other electrode of the selector S1 and the other electrode of the selector S2 are manufactured at the same time.

As described herein, when a magnetization of the free layer 519 is anti-parallel to a magnetization of the reference layer 517, the MTJ structure is in a high resistance state, and when the magnetization of the free layer 519 is parallel to the magnetization of the reference layer 517, the MTJ structure is in a low resistance state. The magnetization of the reference layer 517 is fixed, whereas the magnetization of the free layer 519 is switchable depending on a direction of a write current Iw flowing through the SOT layer 504. The write current Iw does not flow through the MTJ structure. A read current Ir in a read operation or CIM operation flows through the MTJ structure. A resistance of the MTJ structure to the read current Ir corresponds to the resistance of the memory cell 500A to the read current Ir, and depends on the material or a thickness Th of the tunnel barrier layer 518. In some embodiments, as described herein, by adjusting the thickness Th of the tunnel barrier layer 518 comprising MgO, it is possible to advantageously tune the RA of

The memory cell 500a within a wide RA range of 10~10000 Ω·μm². All layers of the memory cell 500A as described with respect to FIG. 5A are BEOL compatible. One or more advantages described herein are achievable by one or more memory devices comprising one or more memory arrays of memory cells 500A, in accordance with some embodiments.

FIG. 5B includes a schematic circuit diagram, and a cross-sectional view of a memory cell 500B, in accordance with some embodiments. In some embodiments, the memory cell 500B corresponds to a memory cell in one or more memory arrays of one or more of the memory devices 100, 200A, 200B, 300, 400A-400C. Components in FIG. 5B having corresponding components in FIG. 5A are designated by the same reference numerals as in FIG. 5A.

As shown in the schematic circuit diagram in FIG. 5B, the memory cell 500B has a memory cell configuration 530 similar to the memory cell configuration 130, with a difference in that the selector S2 in the memory cell configuration 130 is replaced with a diode S3 in the memory cell configuration 530. Specifically, the diode S3 has an anode coupled to a read word line RWL, and a cathode coupled to the MTJ structure. The memory cell configuration 530 is sometimes referred to as 2S-1SOT MRAM with rectifying diode.

As shown in the cross-sectional view in FIG. 5B, the diode S3 comprises a first electrode 531 as a top layer under and in electrical contact wit the read word line 501, and a second electrode 534 as a bottom layer over and in electrical contact with the MTJ structure. The diode S3 further comprises a P-type layer 532 and an N-type layer 533 between the first electrode 531 and the second electrode 534. The P-type layer 532 corresponds to the anode, the N-type layer 533 corresponds to the cathode, and the P-type layer 532 is over the N-type layer 533. In an example configuration in accordance with some embodiments, the P-type layer 532 comprises P-doped CuO, and the N-type layer 533 comprises N-doped IZO. Example materials of the electrodes 531, 534 include, but are not limited to, W, TiN, TaN, C, SiC, or the like. Other materials are within the scopes of various embodiments. All layers of the memory cell 500B as described with respect to FIG. 5B are BEOL compatible. One or more advantages described herein are achievable by one or more memory devices comprising one or more memory arrays of memory cells 500B, in accordance with some embodiments.

FIG. 5C includes a schematic circuit diagram, and a cross-sectional view of a memory cell 500C, in accordance with some embodiments. In some embodiments, the memory cell 500C corresponds to a memory cell in one or more memory arrays of one or more of the memory devices 100, 200A, 200B, 300, 400A-400C.

The memory cell 500C comprises a selector S4 and an STT-MTJ structure coupled in series between a word line 541 and a bit line 543. This memory cell configuration is sometimes referred to as 1S-1STT MRAM. The word line 541 is configured as both a read word line and a write word line. In some embodiments, the selector S4 corresponds to the selector S1 or selector S2.

The selector S4 comprises a first electrode 544 as a top layer under and in electrical contact with the word line 541, a second electrode 546 as a bottom layer over and in electrical contact with the STT-MTJ structure, and a switching layer 545 between the first electrode 544 and second electrode 546. Example materials of the electrodes 544, 546 include, but are not limited to, W, TiN, TaN, C, SiC, or the like. Example materials of the switching layer 545 include, but are not limited to, SiNGeCTe, NGeCTe, GeCTe, SiGeAsTe, AsGeSe, SiAsGeSe, or the like. Other materials are within the scopes of various embodiments.

The STT-MTJ structure comprises a free layer 547 as a top layer, a synthetic antiferromagnetic (SAF) reference layer structure 549 as a bottom layer, and a tunnel barrier layer 548 between the free layer 547 and SAF reference layer structure 549. The free layer 547 is under and in electrical contact with the second electrode 546 of the selector S4. The SAF reference layer structure 549 is over and in electrical contact with the bit line 543. In some embodiments, the SAF reference layer structure 549 comprises one or more magnetic layers and one or more spacers. In an example configuration in accordance with some embodiments, the free layer 547 comprises CoFeB, the tunnel barrier layer 548 comprises MgO, and the SAF reference layer structure 549 comprises CoFeB with one or more spacers. Other materials are within the scopes of various embodiments.

In an example write operation, a sufficiently high write voltage is applied between the word line 541 and bit line 543, causing a write current to flow through the STT-MTJ structure. Depending on the direction of the write current, logic “1” or logic “0” is stored to the STT-MTJ structure. In a read operation or a CIM operation, a read voltage or an input voltage lower than the write voltage is applied between the word line 541 and bit line 543, e.g., the read voltage or the input voltage is supplied to the word line 541 and the bit line 543 is grounded. As a result, the state of the STT-MTJ structure is not changed, and a current flowing through the STT-MTJ structure is output from the memory cell 500C to the bit line 543, to be collected on a corresponding conductor coupling the bit lines of multiple memory arrays, as described herein.

The physical arrangement of various layers of the memory cell 500C as illustrated in FIG. 5C is an example. Other physical arrangement of various layers in the memory cell 500C are within the scopes of various embodiments. For example, in one or more embodiments, the free layer 547 is the bottom layer and the SAF reference layer structure 549 is the top layer of the STT-MTJ structure. In at least one embodiment, the selector S4 is under the STT-MTJ structure. All layers of the memory cell 500C as described with respect to FIG. 5C are BEOL compatible. One or more advantages described herein are achievable by one or more memory devices comprising one or more memory arrays of memory cells 500C, in accordance with some embodiments.

FIG. 5D includes a schematic circuit diagram, and a cross-sectional view of a memory cell 500D, in accordance with some embodiments. In some embodiments, the memory cell 500D corresponds to a memory cell in one or more memory arrays of one or more of the memory devices 100, 200A, 200B, 300, 400A-400C. Components in FIG. 5D having corresponding components in FIG. 5C are designated by the same reference numerals as in FIG. 5C.

The memory cell 500D comprises the selector S4 and a RRAM structure coupled in series between the word line 541 and the bit line 543. This memory cell configuration is sometimes referred to as 1S-1RRAM.

The RRAM structure comprises a reactive electrode 557 as a top layer, an inert electrode 559 as a bottom layer, and a dielectric layer 558 between the reactive electrode 557 and inert electrode 559. The reactive electrode 557 is under and in electrical contact with the second electrode 546 of the selector S4. The inert electrode 559 is over and in electrical contact with the bit line 543. Example materials of the reactive electrode 557 include, but are not limited to, Ti, Ta, Hf, or the like. In some embodiments, the reactive electrode 557 comprises multiple layers. For example, in one or more embodiments, the reactive electrode 557 is a bi-layer, such as Ti/TiN, Ta/TaN, or the like. Example materials of the dielectric layer 558 include, but are not limited to, HfOx, AlOx, TaOx, SiOx, AlNx, or the like. In some embodiments, the dielectric layer 558 comprises multiple layers. For example, the dielectric layer 558 is a bi-layer in one or more embodiments. Example materials of the inert electrode 559 include, but are not limited to, TiN, Ru, Pt, C, or the like. Other materials are within the scopes of various embodiments.

In some embodiments, access operations, including write operations, read operations and CIM operations of the memory cell 500D are performed similarly to access operations of the memory cell 500C.

The physical arrangement of various layers of the memory cell 500D as illustrated in FIG. 5D is an example. Other physical arrangements of various layers in the memory cell 500D are within the scopes of various embodiments. For example, in one or more embodiments, the selector S4 is under the RRAM structure. All layers of the memory cell 500D as described with respect to FIG. 5D are BEOL compatible. One or more advantages described herein are achievable by one or more memory devices comprising one or more memory arrays of memory cells 500D, in accordance with some embodiments.

In some embodiments, a memory cell (not shown) is implemented with the PCM technology. Such a memory cell, in one or more embodiments, comprises one selector as described herein, and a PCM structure. This memory cell configuration is sometimes referred to as 1S-1PCM. In some embodiments, a memory cell (not shown) is implemented with the ECRAM technology. Such a memory cell, in one or more embodiments, comprises two selectors as described herein, and an ECRAM structure. This memory cell configuration is sometimes referred to as 2S-1ECRAM. All layers of the described memory cells implemented with the PCM and/or ECRAM technologies are BEOL compatible. One or more advantages described herein are achievable by one or more memory devices comprising one or more memory arrays of memory cells implemented with the PCM and/or ECRAM technologies, in accordance with some embodiments.

In one or more of the memory cells described with respect to FIGS. 5A-5D, selectors and/or diodes are configured as access circuit elements for enabling or disabling access operations in the memory cells. In some embodiments, one or more of the described selectors and/or diodes are replaceable by transistors, for example, BEOL transistors, as described with respect to FIGS. 6A-6B.

FIG. 6A is a schematic circuit diagram of a memory cell 600A, in accordance with some embodiments. In some embodiments, the memory cell 600A corresponds to a memory cell in one or more memory arrays of one or more of the memory devices 100, 200A, 200B, 300, 400A-400C. Components in FIG. 6A having corresponding components in FIG. 1A are designated by the same reference numerals as in FIG. 1A.

Compared to a memory cell having the memory cell configuration 130, the memory cell 600A comprises transistors T1, T2 correspondingly in place of selectors S1, S2. In at least one embodiment, one of the selectors S1, S2 is maintained, whereas the other of the selectors S1, S2 is replaced by the corresponding transistor T1 or T2. In the example configuration in FIG. 6A, the transistor T1 has a gate coupled to the write word line WWL, a first source/drain coupled to a source line SL, and a second source/drain coupled to one end of a SOT layer. An opposite end of the SOT layer is coupled to a bit line BL. The transistor T2 has a gate coupled to the read word line RWL, a first source/drain coupled to the source line SL, and a second source/drain coupled to an MTJ structure. The MTJ structure is in electrical contact with the SOT layer as described with respect to the memory cell configuration 130. In at least one embodiment, the source line SL and bit line switch place. The transistors T1, T2 are N-type transistors. In some embodiments, at least one of the transistors T1, T2 is a P-type transistor. The memory cell configuration described with respect to FIG. 6A is sometimes referred to as 2T-1SOT MRAM.

In an example write operation, an access voltage is supplied to the write word line WWL to turn ON the transistor T1, while the transistor T2 is turned OFF. A write voltage is applied between the source line SL and the bit line BL, causing a write current to flow through the SOT layer. Depending on the direction of the write current, logic “1” or logic “0” is stored to the MTJ structure. In a read operation or a CIM operation, an access voltage is supplied to the read word line RWL to turn ON the transistor T2, while the transistor T1 is turned OFF. A read voltage or an input voltage is applied between the source line SL and the bit line BL, e.g., the read voltage or the input voltage is supplied to the source line SL and the bit line BL is grounded. As a result, a current flowing through the MTJ structure is output from the memory cell 600A to the bit line BL, to be collected on a corresponding conductor coupling the bit lines of multiple memory arrays, as described herein. One or more advantages described herein are achievable by one or more memory devices comprising one or more memory arrays of memory cells 600A, in accordance with some embodiments.

FIG. 6B is a schematic cross-sectional view of a memory device 600B, in accordance with some embodiments. In some embodiments, the memory device 600B corresponds to one or more of the memory devices 100, 200A, 200B, 300, 400A-400C.

The memory device 600B comprises a substrate 640, at least one transistor 650 over the substrate 640, and a BEOL structure 660 over the transistor 650 and the substrate 640. The transistor 650 is an example of a transistor of FEOL circuitry, as described with respect to FIGS. 1A, 4A-4C. The transistor 650 serves as an example of transistors constituting various circuits in the memory device 600B including, but not limited to, word line drivers, bit line drivers, sensing circuits, BL selection circuits, current summation circuits, a memory controller, MAC circuits, ADCs, or the like.

In some embodiments, the substrate 640 is a semiconductor substrate. N-type and P-type dopants are added to the substrate to correspondingly form N wells 651, 652, and P wells (not shown). In some embodiments, isolation structures are formed between adjacent P wells and N wells. For simplicity, several features such as P wells and isolation structures are omitted from FIG. 6B.

The transistor 650 comprises a gate and source/drains. The N wells 651, 652 configure the source/drains of the transistor 650. The gate of the transistor 650 comprises a stack of gate dielectric layers 653, 654, and a gate electrode 655. In at least one embodiment, the transistor 650 comprises a single gate dielectric layer instead of a stack of multiple gate dielectric layers. Example materials of the gate dielectric layer or layers include HfO2, ZrO2, or the like. Example materials of the gate electrode 655 include polysilicon, metal, or the like. The described configuration of the transistor 650 is an example. Various transistor configurations are within the scopes of various embodiments, including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The memory device 600B further comprises contact structures configured to electrically couple the transistor 650 to other circuitry in the memory device 600B. The contact structures comprise source/drain (metal-to-device, or MD) contacts 656, 657 correspondingly over and in electrical contact with the source/drains 651, 652. The contact structures further comprise various vias. For example, a via-to-gate (VG) via 645 is over and in electrical contact with the gate electrode 655. Via-to-device (VD) vias 658, 659 are correspondingly over and in electrical contact with the MD contacts 656, 657. The VG via 645 and/or VD vias 658, 659 are configured to couple the transistor 650 to various patterns in an M0 layer of the BEOL structure 660, as described herein.

The BEOL structure 660 comprise a plurality of metal layers M0, M1,. . . and a plurality of via layers VIA0, VIA1,. . . arranged alternatingly in a thickness direction, i.e., a Z direction, of the substrate 640. The BEOL structure 660 further comprises various interlayer dielectric (ILD) layers (not shown) in which the metal layers and via layers are embedded. The M0 layer, i.e., metal-zero (M0) layer, is the lowermost metal layer immediately over and in electrical contact with the VD and VG vias, and is schematically illustrated in the drawings with the label “M0.” The M1 layer is the metal layer immediately over the M0 layer. The BEOL structure 660 further comprises other metal layers sequentially stacked over the M1 layer. The BEOL structure 660 also comprises via layers arranged between and electrically couple successive metal layers. A via layer VIAn is arranged between and electrically couple the Mn layer and the Mn+1 layer, where n is an integer form zero and up. For example, a via-zero (VIA0) layer is the lowermost via layer which is arranged between and electrically couple the M0 layer and the M1 layer, a VIA1 layer is arranged between and electrically couple the M1 layer and the M2 layer, or the like. The metal layers and via layers of the BEOL structure 660 are configured to form interconnects that electrically couple various elements or circuits of the memory device 600B with each other, and with external circuitry. A structure below the M0 layer and including the transistor 650 is manufactured by front-end-of-line (FEOL) processing, and is sometimes referred to as an FEOL structure. For example, the transistor 650 is an FEOL transistor. In contrast, the BEOL structure 660 structure includes the M0 layer and above is manufactured by back-end-of-line (BEOL) processing.

In some embodiments, the BEOL structure 660 comprises one or more stacked memory arrays, or decks, and corresponding memory cells of the memory device 600B. For example, one or more of Deck-1, Deck-2 to Deck-J described with respect to FIGS. 4A-4C and/or one or more of the memory cells 500A-500D, 600A are parts of the BEOL structure 660. For example, FIG. 6B includes a schematic cross-sectional view of a BEOL transistor 680 corresponding to one or more of the transistors T1, T2 of the memory cell 600A. Other features of the memory cell 600A, such as the MTJ structure and SOT layer, are configured, in one or more embodiments, as described with respect to FIGS. 5A-5B.

The transistor 680 comprises a gate electrode 683 over a dielectric layer 692 in the BEOL structure 660, a gate dielectric layer 682 over the gate electrode 683 and the dielectric layer 692, and a semiconductor material layer, such as a metal oxide layer 681, over the gate dielectric layer 682. A portion of the metal oxide layer 681 over the gate electrode 683 defines a channel of the transistor 680. Portions of the metal oxide layer 681 on opposite sides of the channel define source/drains 684, 685. Contact structures 686, 687 are in a dielectric layer 694, and are correspondingly over and in electrical contact with the source/drains 684, 685. Vias 688, 689 are correspondingly over and in electrical contact with the contact structure 686, contact structure 687. A via 690 is in the dielectric layer 692, under and in electrical contact with the gate electrode 683. The via 688 is configured to couple the source/drain 684 to the SOT layer or MTJ structure (depending on whether the transistor 680 corresponds to the transistor T1 or T2). The via 689 is configured to couple the source/drain 685 to the source line SL. The via 690 is configured to couple the gate electrode 683 to the write word line WWL or read word line RWL (depending on whether the transistor 680 corresponds to the transistor T1 or T2). Example materials of the metal oxide layer 681 include, but are not limited to, indium tungsten oxide (IWO), indium zinc oxide (IZO), indium tin oxide (ITO), indium gallium oxide (IGO), aluminum zinc oxide (AZO), gallium zinc oxide (GZO), gallium oxide (GaO), indium oxide (InO), zinc oxide (ZnO), or the like, or a combination thereof. In at least one embodiment, each of the described materials for the metal oxide layer 681 is doped or undoped. In some embodiments, the metal oxide layer 681 is a single layer such as an InGaZnO4 (IGZO) layer. In some embodiments, the metal oxide layer 681 has a multi-layer structure, e.g., an IGZO layer and an InO layer over the IGZO layer. In an example configuration, In some embodiments, the metal oxide layer 681 comprises IGZO, the gate dielectric layer 682 comprises SiO2, and the gate electrode 683 and the contact structures 686, 687 comprise TiN. Other materials and/or BEOL transistor configurations are within the scopes of various embodiments. For example, in one or more embodiments, instead of the gate electrode 683 being a bottom gate electrode under the metal oxide layer 681, a BEOL transistor comprises a top gate electrode over the metal oxide layer 681. In some situations, BEOL transistors are larger and/or require more cell areas than BEOL selectors and diodes, such as selectors S1, S2 and diode S3 described with respect to FIGS. 5A-5B. One or more advantages described herein are achievable by the memory device 600B, in accordance with some embodiments.

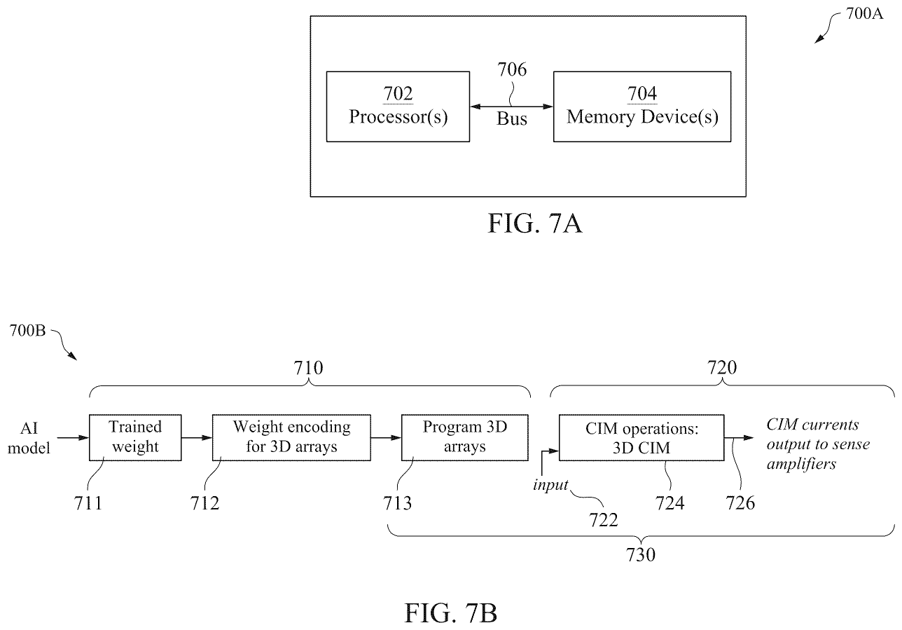

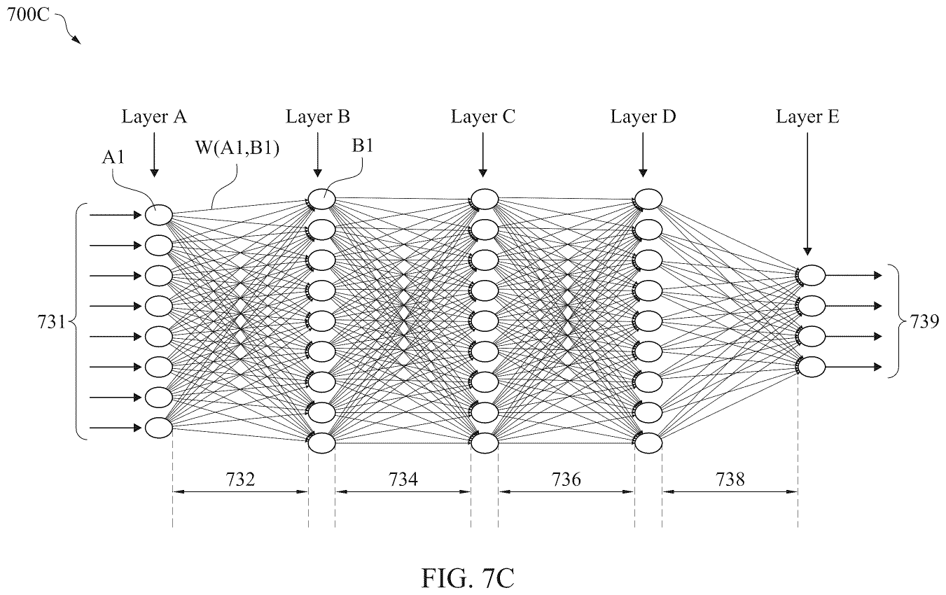

FIG. 7A is a schematic diagram of an integrated circuit (IC) device 700A, in accordance with some embodiments.

The IC device 700A comprises one or more hardware processors 702, one or more memory devices 704 coupled to the processors 702 by one or more buses 706. In some embodiments, the IC device 700A comprises one or more further circuits including, but not limited to, cellular transceiver, global positioning system (GPS) receiver, network interface circuitry for one or more of Wi-Fi, USB, Bluetooth, or the like. Examples of the processors 702 include, but are not limited to, a central processing unit (CPU), a multi-core CPU, a neural processing unit (NPU), a graphics processing unit (GPU), a digital signal processor (DSP), a field-programmable gate array (FPGA), an application-specific integrated circuit (ASIC), other programmable logic devices, a multimedia processor, an image signal processors (ISP), or the like. Examples of the memory devices 704 include one or more memory devices described herein. In at least one embodiment, each of the processors 702 is coupled to a corresponding memory device among the memory devices 704.

In some embodiments, one or more of the memory devices 704 are configured to perform one or more CIM operations and/or CIM functions, as described herein. As a result, it is possible in one or more embodiments to reduce the computing workload of the corresponding processor 702, reduce memory access time, and/or improve performance. In at least one embodiment, the IC device 700A is a system-on-a-chip (SOC). In at least one embodiment, one or more advantages described herein are achievable by the IC device 700A.

FIG. 7B is a schematic diagram showing various operations in a CIM process 700B, in accordance with some embodiments.

The CIM process 700B comprises a first phase 710, and a second phase 720. The first phase 710 is performed to program or write weight data into various stacked memory arrays (or 3D arrays) of a memory device 730. In some embodiments, the memory device 730 corresponds to one or more of the memory devices 100, 200A, 200B, 300, 400A-400C, 600B, 704, and the 3D arrays of the memory device 730 correspond to one or more of the stacked memory arrays or stacked decks as described herein. The second phase 720 is performed in or by the memory device 730, using the weight data programed in the 3D arrays, to compute various CIM operations including at least one 3D CIM operation. In some embodiments, the first phase 710 is omitted.

In the example configuration in FIG. 7B, the first phase 710 comprises stages 711-713. At stage 711, trained weight data for a model, such as an AI model, are obtained. In some embodiments, the AI model is already trained ex situ, e.g., externally by a CPU or GPU of IC device outside the memory device 730. In at least one embodiment, the externally trained weight data are loaded into a buffer of the memory device 730 or an IC device comprising the memory device 730.

At stage 712, the trained weight data loaded from the buffer are encoded for the 3D arrays of the memory device 730. For example, analog weight data are encoded for a memory array of multi-level memory cells, such as RRAM or PCM. Alternatively, analog weight data are encoded for several stacked memory arrays of binary memory cells, such as MRAM. Example combinations of stacked binary memory cells into an equivalent multi-level memory cell are described with respect to FIG. 2A. In at least one embodiment, stage 712 is performed by a processor of the IC device or by a memory controller of the memory device 730.

At stage 713, the encoded weight data are programmed, or written, into the corresponding memory arrays of the memory device 730. In some embodiments, write operations are controlled by the memory controller. In at least one embodiment, write operations are performed parallel in different memory arrays, for example, as described with respect to FIG. 3A.

In the second phase 720, at stage 724, one or more CIM operations are performed using the programmed weight data and input data 722. The one or more CIM operations comprise at least one 3D CIM operation, such as MVM, as described herein. CIM currents resulting from the one or more CIM operations are output, by output operation 726, to one or more sensing circuits, e.g., sense amplifiers, and results of the CIM operations are determined based on the sensed CIM currents. As described herein, in some embodiments, different CIM operations are performed by different sets of stacked memory arrays among the 3D arrays of the memory device 730. As also described herein, in some embodiments, several stacked memory arrays are configured to work together to implement a memory array of equivalent multi-level memory cells for handling analog weight data, thanks to the current summations along the vertical paths.

In some embodiments, the first phase 710 is performed once for a given model, and then the programmed weight data of the model are used for subsequent CIM operations in the second phase 720. In at least one embodiment, based on the results of one or more CIM operations, it is determined, e.g., by an operator or computer system, to update weight data, and the first phase 710 is performed again to program the updated weight data into the 3D arrays of the memory device 730.

In some embodiments, a model is trained in situ, i.e., in or by the memory device 730. For example stages 711-713 and 724 are performed repeatedly in multiple iterations. Results of CIM operations output by the stage 724 during this in situ training are not used for real-world applications, but are used as feedback for tuning, or training, weight data of the model. Upon completion of the in situ training, e.g., convergence of the weight data, the trained weight data programed in the 3D arrays of the memory device 730 are used in CIM operations at the stage 724 for real-world applications. Other configurations are within the scopes of various embodiments. One or more advantages described herein are achievable by the CIM process 700B, in accordance with some embodiments.

FIG. 7C is a schematic diagram of a neural network 700C, in accordance with some embodiments.

The neural network 700C comprises a plurality of layers A-E each comprising a plurality of nodes (or neurons). The nodes in successive layers of the neural network 700C are connected with each other by a matrix or array of connections. For example, the nodes in layers A and B are connected with each other by connections in a matrix 732, the nodes in layers B and C are connected with each other by connections in a matrix 734, the nodes in layers C and D are connected with each other by connections in a matrix 736, and the nodes in layers D and E are connected with each other by connections in a matrix 738. Layer A is an input layer configured to receive input data 731. The input data 731 propagate through the neural network 700C, from one layer to the next layer via the corresponding matrix of connections between the layers. As the data propagate through the neural network 700C, the data undergo one or more computations, and are output as output data 739 from layer E which is an output layer of the neural network 700C. Layers B, C, D between input layer A and output layer E are sometimes referred to as hidden or intermediate layers. The number of layers, number of matrices of connections, and number of nodes in each layer in FIG. 7C are examples. Other configurations are within the scopes of various embodiments. For example, in at least one embodiment, the neural network 700C includes no hidden layer, and has an input layer connected by one matrix of connections to an output layer. In one or more embodiments, the neural network 700C has one, two, or more than three hidden layers.

In some embodiments, at least one of the matrices 732, 734, 736, 738 is implemented by stacked memory arrays as described herein. Specifically, in the matrix 732, a connection between a node in layer A and another node in layer B has a corresponding weight. For example, a connection between node A1 and node B1 has a weight W(A1,B1) which corresponds to weight data stored, e.g., in various stacked memory cells combined with each other for implementing a multi-level memory cell, as described herein. In some embodiments, the weight data in one or more of the stacked memory arrays are updated, e.g., by a processor and/or through a memory controller, as machine learning is performed using the neural network 700C. One or more advantages described herein are achievable in the neural network 700C implemented in whole or in part by one or more memory devices in accordance with some embodiments.

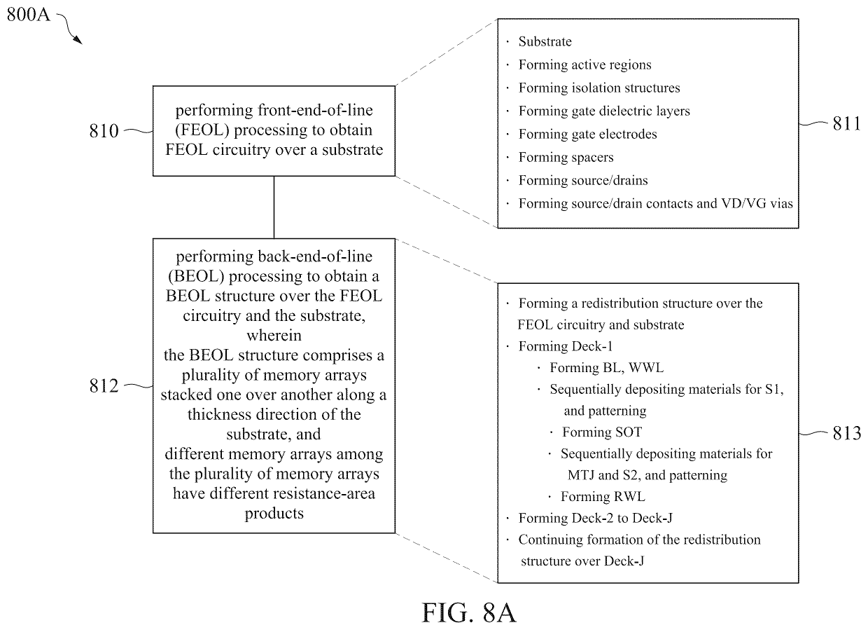

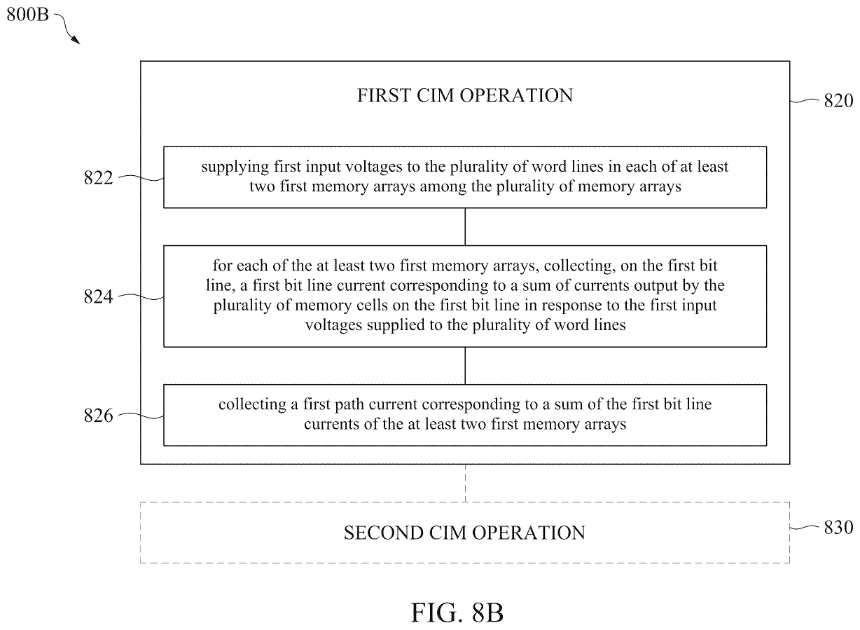

FIG. 8A is a flowchart of a method 800A, in accordance with some embodiments. In some embodiments, the method 800A is performed to manufacture a memory device corresponding to one or more of the memory devices 100, 200A, 200B, 300, 400A-400C, 600B, 704. The method 800A comprises operations 810, 812.

At operation 810, front-end-of-line (FEOL) processing is performed to obtain FEOL circuitry over a substrate. For example, as described with respect to FIG. 6B, FEOL processing is performed to obtain, over a substrate 640, an FEOL structure under the M0 layer. The FEOL structure comprises FEOL circuitry, represented by a transistor 650. In some embodiments, the FEOL circuitry comprises a memory controller, as described with respect to one or more of FIGS. 2A, 4A-4C, 6B.

At operation 812, back-end-of-line (BEOL) processing is performed to obtain a BEOL structure over the FEOL circuitry and the substrate. The BEOL structure comprises a plurality of memory arrays stacked one over another along a thickness direction of the substrate. Different memory arrays among the plurality of memory arrays have different resistance-area products (RAs). For example, as described with respect to FIG. 6B, BEOL processing is performed to obtain, over the FEOL circuitry and substrate 640, a BEOL structure 660. The BEOL structure 660 comprises metal layers and via layers configured to form interconnects coupling circuit elements of the FEOL circuitry with each other, with stacked memory arrays in the BEOL structure 660, and/or with external circuitry. Various stacked memory arrays are formed as parts of the BEOL structure 660, as described with respect to one or more of FIGS. 2A-2B, 4A-4C, 5A-5D, 6A-6B. In some embodiments, at least two memory arrays among the stacked memory arrays are formed, in the BEOL processing, correspondingly by different memory technologies, including, but not limited to, SOT MRAM, STT MRAM, RRAM, PCM, FeRAM, ECRAM, or the like. The stacked memory arrays comprise memory arrays with different RAs, for example, MRAM memory arrays which have tunnel barrier layers with different thicknesses. One or more advantages described herein are achievable by memory devices manufactured by the method 800A, in accordance with some embodiments.

An example sequence 811 of manufacturing processes in operation 810 is also illustrated in FIG. 8A and is described herein with respect to FIG. 6B.

In the example sequence 811, the manufacturing process starts from a substrate, e.g., the substrate 640. The substrate 640 comprises, in at least one embodiment, a silicon substrate. The substrate 640 comprises, in at least one embodiment, silicon germanium (SiGe), Gallium arsenic, or other suitable semiconductor materials. In some embodiments, the substrate 640 comprises an insulating substrate or a silicon on insulator (SOI) substrate. Active regions, e.g., PMOS active regions and/or NMOS active regions, are formed in or over the substrate 640, using one or more masks. Isolation structures (not shown) are formed in the substrate 640, e.g., by etching corresponding areas of the substrate 640 and filling the etched areas with insulating material.

Various transistors are formed over the substrate 640 in the FEOL processing. For example, at least one gate dielectric material layer is deposited over the substrate 640. Example materials of the gate dielectric material layer include, but are not limited to, a high-k dielectric layer, an interfacial layer, and/or combinations thereof. In some embodiments, the gate dielectric material layer is deposited over the substrate by atomic layer deposition (ALD) or other suitable techniques.

A gate electrode layer is deposited over the gate dielectric material layer. Example materials of the gate electrode layer include, but are not limited to, polysilicon, metal, Al, AlTi, Ti, TiN, TaN, Ta, TaC, TaSiN, W, WN, MoN, and/or other suitable conductive materials. In some embodiments, the gate electrode layer is deposited by chemical vapor deposition (CVD), physical vapor deposition (PVD or sputtering), plating, atomic layer deposition (ALD), and/or other suitable processes.

A patterning process is then performed, using one or more masks to pattern the gate dielectric material layer and gate electrode layer into a plurality of gate structures (or gate stacks), each comprising a gate electrode, such as a gate electrode 655, and one or more underlying gate dielectric layers, such as gate dielectric layers 653, 654. In some embodiments, the patterning of the gate dielectric material layer and gate electrode layer includes a photolithography operation.

In at least one embodiment, spacers (not shown) are formed, by deposition and patterning, on opposite sides of each gate electrode. Example materials of the spacers include, but are not limited to, silicon nitride, oxynitride, silicon carbide and other suitable materials. Example deposition processes include, but are not limited to, plasma enhanced chemical vapor deposition (PECVD), low-pressure chemical vapor deposition (LPCVD), sub-atmospheric chemical vapor deposition (SACVD), atomic layer deposition (ALD), or the like. Example patterning processes include, but are not limited to, a wet etch process, a dry etch process, or combinations thereof.

Source/drains, such as source/drains 651, 652, are formed in the active regions of the substrate 640. In at least one embodiment, the source/drains are formed by using the gate electrodes and the spacers as a mask. For example, the formation of the source/drains is performed by an ion implantation or a diffusion process. Depending on the type of the devices or transistors, the source/drains are doped with P-type dopants, such as boron or BF₂, N-type dopants, such as phosphorus or arsenic, and/or combinations thereof. As a result, transistors of both P-type and N-type are formed in one or more circuit regions of FEOL circuitry.

MD contacts and VD/VG vias are formed over the source/drains and gate electrodes. In an example manufacturing process, a conductive layer, e.g., a metal, is deposited over the substrate with the transistors formed thereon, thereby making electrical connections to the source/drains of the transistors. A planarizing process is performed to planarize the conductive layer, resulting in MD contacts, such as MD contacts 656, 657. Various VD vias, e.g., 658, 659, and VG vias, e.g., 645, are formed correspondingly over the MD contacts and gate electrodes. A resulting FEOL structure comprising the FEOL circuitry over the substrate 640 is obtained at the end of the FEOL processing.

After the FEOL processing, a BEOL processing is performed as described with respect to operation 812. An example sequence 813 of manufacturing processes in operation 812 is also illustrated in FIG. 8A and is described herein with respect to FIG. 5A.

In the example sequence 813, a redistribution structure is formed over the FEOL structure to electrically couple various elements or circuits of the FEOL structure with each other, and with further circuitry including various memory arrays to be formed. In at least one embodiment, the redistribution structure comprises sequentially overlying metal and via layers. The overlying metal layers and via layers correspondingly comprise metal layers M0, M1, or the like, and via layers VIA0, VIA1, or the like. For example, the formation of the M0 layer comprises depositing a metal material and patterning the deposited metal materials to form various metal patterns coupled to the underlying VD/VG vias. In at least one embodiment, the redistribution structure is manufactured sequentially layer by layer upward from the patterned M0 layer, for example, by repeatedly performing a damascene process. In such a damascene process, a dielectric layer is deposited over a patterned Mk layer (k is zero and up). The dielectric layer is patterned to form a damascene structure having underlying via holes corresponding to conductive vias of a via layer Vk to be formed later, and overlying recessed features corresponding to metal patterns of a metal layer Mk+1 to be formed latter. An example patterning process to form the damascene structure comprises two or more photolithographic patterning and anisotropic etching steps to first form the underlying via holes, then form the overlying recessed features. A conductive material is deposited to fill in the damascene structure to obtain the conductive vias in the via layer Vk and overlying metal patterns in the metal layer Mk+1. The described damascene process is performed one or more times to sequentially form vias and metal patterns of higher via layers and metal layers of the redistribution structure.

In some embodiments, various memory arrays, or Decks, are formed as the redistribution structure is being built up. For example, the lowest or bottom memory array, e.g., Deck-1, is formed in accordance with the configuration of the memory cell 500A described with respect to FIG. 5A.

In the formation of Deck-1 in accordance with some embodiments, a bit line 503 is formed as a metal pattern in a metal layer of the redistribution structure. A via 508 in a via layer of the redistribution structure is formed over and in electrical contact with the bit line 503. In at least one embodiment, the via 508 comprises an interconnect comprising one or more metal patterns and one or more vias. A write word line 502 and a metal pattern 507 are formed as metal patterns in a further metal layer of the redistribution structure. The metal pattern 507 is over and in electrical contact with the via 508. A via 506 in a further via layer of the redistribution structure is formed over and in electrical contact with the metal pattern 507. In at least one embodiment, the via 506 comprises an interconnect comprising one or more metal patterns and one or more vias.

A selector S1 is formed over and in electrical contact with the write word line 502. In some embodiments, materials of a second electrode 513, a switching layer 512, and a first electrode 511 are sequentially deposited, e.g., by PVD, CVD, PECVD, ALD, or the like, over the write word line 502 to obtain a multilayer structure. The deposited multilayer structure is then patterned, e.g., by photolithography and etching processes, to obtain the selector S1. Example materials of the electrodes 511, 513 include, but are not limited to, W, TiN, TaN, C, SiC, or the like. Example materials of the switching layer 512 include, but are not limited to, SiNGeCTe, NGeCTe, GeCTe, SiGeAsTe, AsGeSe, SiAsGeSe, or the like.

A SOT layer 504 is formed over and in electrical contact with the via 506 and the first electrode 511. In some embodiments, a material of the SOT layer 504 is deposited, e.g., by PVD, CVD, PECVD, ALD, or the like, over the via 506 and the first electrode 511. The deposited material is then patterned, e.g., by photolithography and etching processes, to obtain the SOT layer 504. Example materials of the SOT layer 504 include, but are not limited to, W, doped-W, Pt, Ta, 2D materials such as BeSe2, or the like.

An MTJ structure and a selector S2 are formed over and in electrical contact with the SOT layer 504. In some embodiments, materials of a free layer 519, a tunnel barrier layer 518, a reference layer 517, a second electrode 516, a switching layer 515, and a first electrode 514 are sequentially deposited, e.g., by PVD, CVD, PECVD, ALD, or the like, over the SOT layer 504 to obtain a multilayer structure. The deposited multilayer structure is then patterned, e.g., by photolithography and etching processes, to obtain the MTJ structure and the selector S2 over the MTJ structure. In an example configuration in accordance with some embodiments, the reference layer 517 comprises CoFeB, the tunnel barrier layer 518 comprises MgO, and the free layer 519 comprises CoFeB. Example materials of the electrodes 514, 516 include, but are not limited to, W, TiN, TaN, C, SiC, or the like. Example materials of the switching layer 515 include, but are not limited to, SiNGeCTe, NGeCTe, GeCTe, SiGeAsTe, AsGeSe, SiAsGeSe, or the like.

A read word line 501 is formed over and in electrical contact with the first electrode 514. In at least one embodiment, the read word line 501 is formed as a metal pattern in a further metal layer of the redistribution structure. The formation of Deck-1 is completed.

Subsequent to the formation of Deck-1, one or more further memory arrays, e.g., Deck-2 to Deck-J, is/are sequentially formed over Deck-1. In some embodiments, the formation of at least one of Deck-2 to Deck-J is the same as the formation of Deck-1, except that the thickness of the tunnel barrier layer 518 is different from one memory array to another, thereby obtaining different RAs in different memory arrays. In some embodiments, between two successive memory arrays, one or more metal layers and/or via layers of the redistribution structure are formed to couple the memory arrays with each other and/or with the FEOL circuitry.

Upon completion of the formation of the top memory array, i.e., Deck-J, the formation of the redistribution structure is continued, to form one or more metal layers and/or via layers over Deck-J for, e.g., connections to external circuitry. The described sequence 813 based on the configuration of the memory cell 500A is an example. Other sequences and/or memory cell configurations are within the scopes of various embodiments.

In some embodiments, at least one memory array of Deck-1 to Deck-J is formed in accordance with the configuration of the memory cell 500B described with respect to FIG. 5B.

For example, the formation of the memory array in accordance with configuration of the memory cell 500B is similar to the sequence 813 up to the SOT layer 504. An MTJ structure and a selector S3 are next formed over and in electrical contact with the SOT layer 504. In some embodiments, materials of a free layer 519, a tunnel barrier layer 518, a reference layer 517, a second electrode 534, an N-type layer 533, a P-type layer 532, and a first electrode 531 are sequentially deposited, e.g., by PVD, CVD, PECVD, ALD, or the like, over the SOT layer 504 to obtain a multilayer structure. The deposited multilayer structure is then patterned, e.g., by photolithography and etching processes, to obtain the MTJ structure and the selector S3 over the MTJ structure. In an example configuration in accordance with some embodiments, the P-type layer 532 comprises P-doped CuO, and the N-type layer 533 comprises N-doped IZO. Example materials of the electrodes 531, 534 include, but are not limited to, W, TiN, TaN, C, SiC, or the like. A read word line 501 is formed over and in electrical contact with the first electrode 531. In at least one embodiment, the read word line 501 is formed as a metal pattern in a further metal layer of the redistribution structure. The formation of the memory array is completed.

In some embodiments, at least one memory array of Deck-1 to Deck-J is formed in accordance with the configuration of the memory cell 500C described with respect to FIG. 5C.

For example, a bit line 543 is formed as a metal pattern in a metal layer of the redistribution structure. An STT-MTJ structure and a selector S4 are formed over and in electrical contact with the bit line 543. In some embodiments, materials of a SAF reference layer structure 549, tunnel barrier layer 548, free layer 547, a second electrode 546, a switching layer 545, and a first electrode 544 are sequentially deposited, e.g., by PVD, CVD, PECVD, ALD, or the like, over the bit line 543 to obtain a multilayer structure. The deposited multilayer structure is then patterned, e.g., by photolithography and etching processes, to obtain the MTJ structure and the selector S4 over the MTJ structure. In an example configuration in accordance with some embodiments, the free layer 547 comprises CoFeB, the tunnel barrier layer 548 comprises MgO, and the SAF reference layer structure 549 comprises CoFeB with one or more spacers. Example materials of the electrodes 544, 546 include, but are not limited to, W, TiN, TaN, C, SiC, or the like. Example materials of the switching layer 545 include, but are not limited to, SiNGeCTe, NGeCTe, GeCTe, SiGeAsTe, AsGeSe, SiAsGeSe, or the like. A word line 541 is formed over and in electrical contact with the first electrode 544. In at least one embodiment, the word line 541 is formed as a metal pattern in a further metal layer of the redistribution structure. The formation of the memory array is completed.

In some embodiments, at least one memory array of Deck-1 to Deck-J is formed in accordance with the configuration of the memory cell 500D described with respect to FIG. 5D.

For example, a bit line 543 is formed as a metal pattern in a metal layer of the redistribution structure. A RRAM structure and a selector S4 are formed over and in electrical contact with the bit line 543. In some embodiments, materials of an inert electrode 559, a dielectric layer 558, a reactive electrode 557, a second electrode 546, a switching layer 545, and a first electrode 544 are sequentially deposited, e.g., by PVD, CVD, PECVD, ALD, or the like, over the bit line 543 to obtain a multilayer structure. The deposited multilayer structure is then patterned, e.g., by photolithography and etching processes, to obtain the RRAM structure and the selector S4 over the RRAM structure. Example materials of the reactive electrode 557 include, but are not limited to, Ti, Ta, Hf, or the like. In some embodiments, the reactive electrode 557 comprises multiple layers. For example, in one or more embodiments, the reactive electrode 557 is a bi-layer, such as Ti/TiN, Ta/TaN, or the like. Example materials of the dielectric layer 558 include, but are not limited to, HfOx, AlOx, TaOx, SiOx, AlNx, or the like. In some embodiments, the dielectric layer 558 comprises multiple layers. For example, the dielectric layer 558 is a bi-layer in one or more embodiments. Example materials of the inert electrode 559 include, but are not limited to, TiN, Ru, Pt, C, or the like. A word line 541 is formed over and in electrical contact with the first electrode 544. In at least one embodiment, the word line 541 is formed as a metal pattern in a further metal layer of the redistribution structure. The formation of the memory array is completed.

In some embodiments, at least one memory array of Deck-1 to Deck-J is formed in accordance with the configuration of the memory cell 600A described with respect to FIG. 6A. In at least one embodiment, at least one of a transistor T1 or transistor T2 is formed as a BEOL transistor, e.g., BEOL transistor 680 described with respect to FIG. 6B.

For example, a via 690 is formed in a dielectric layer 692 of the redistribution structure, e.g., by etching and metal filling, to configure a connection to a corresponding write word line WWL or read word line RWL. In some embodiments, the via 690 belongs to a via layer of the redistribution structure.

A gate electrode 683 is formed over the via 690 to be electrically coupled to the corresponding write word line WWL or read word line RWL. Example materials of the gate electrode 683 include, but are not limited to, Cu, Al, Ti, Ta, W, Ru, Co, Ni, or the like, an alloy thereof, or a combination thereof. In some embodiments, the gate electrode 683 is formed by depositing the gate electrode material over the dielectric layer 692 with the via 690 formed therein, e.g., by CVD, PVD, plating, ALD, and/or other suitable processes. The deposited gate electrode material is then patterned to form the gate electrode 683, e.g., by photolithography and etching processes.

A gate dielectric layer 682 is formed over the obtained structure including the gate electrode 683. Example materials of the gate dielectric layer 682 include, but are not limited to, silicon oxide, silicon oxynitride, high-k materials, or the like. Example high-k materials include, but are not limited to, zirconium dioxide (ZrO2), aluminum oxide (Al2O3), hafnium oxide (HfO2), tantalum oxide (Ta2O5), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate, zirconium aluminate, titanium oxide, a hafnium dioxide-alumina (HfO2-Al2O3) alloy, or the like, or a combination thereof. In some embodiments, the gate dielectric layer 682 is a single layer. In some embodiments, the gate dielectric layer 682 has a multi-layer structure. In some embodiments, gate dielectric layer 682 is deposited by PVD, CVD, PECVD, ALD, or the like.

A semiconductor material layer, e.g., metal oxide layer 681, is formed over the gate dielectric layer 682. Example materials of the metal oxide layer 681 include, but are not limited to, indium tungsten oxide (IWO), indium zinc oxide (IZO), indium tin oxide (ITO), indium gallium oxide (IGO), aluminum zinc oxide (AZO), gallium zinc oxide (GZO), gallium oxide (GaO), indium oxide (InO), zinc oxide (ZnO), or the like, or a combination thereof. In some embodiments, the metal oxide layer 681 is deposited by PVD, CVD, PECVD, ALD, or the like. In some embodiments, the metal oxide layer 681 is doped. In at least one embodiment, the metal oxide layer 681 is undoped. The deposited metal oxide layer 681 is patterned, e.g., by photolithography and etching processes, to expose portions of the gate dielectric layer 682 on opposite sides of the gate electrode 683.

A dielectric layer, e.g., dielectric layer 694, is formed over the metal oxide layer 681 to cover the exposed portions of the gate dielectric layer 682. Example materials of the dielectric layer 694 including, but not limited to, silicon oxide, silicon nitride, silicon oxynitride, aluminum oxide, aluminum nitride, or the like, or a combination thereof. In some embodiments, the dielectric layer 694 is deposited by PVD, CVD, PECVD, ALD, a spin-on technique, or the like.

Contact structures, e.g., contact structures 686, 687, are formed in the dielectric layer 694 to be over and in electrical contact with source/drains 684, 685 configured by the metal oxide layer 681. For example, openings are formed, e.g., by etching, in the dielectric layer 694 in locations where the contact structures 686, 687, are to be formed, to expose the underlying source/drains 684, 685. A conductive material, e.g., a metal, is filled in the openings, and a planarization process is then performed to obtain the contact structures 686, 687. Example conductive materials of the contact structures 686, 687 include, but are not limited to, Cu, Al, Ti, Ta, W, Ru, Co, Ni, or the like, an alloy thereof, or a combination thereof. In some embodiments, the conductive material of the source/drains 684, 685 is deposited by PVD, CVD, PECVD, ALD, or the like. As a result, the BEOL transistor 680, is obtained.

In at least one embodiment, the formation of the memory array in accordance with the configuration of the memory cell 600A further comprises forming a SOT layer and an MTJ structure in a manner similar to the sequence 813. In at least one embodiment, the formation of the memory array in accordance with the configuration of the memory cell 600A further comprises forming a source line SL, a bit line BL, a read word line RWL, a write word line WWL as metal patterns in various metal layers of the redistribution structure. In some embodiments, the SOT layer and MTJ structure are formed at least partially below, or before, the transistor 680. In at least one embodiment, the SOT layer and MTJ structure are formed at least partially above, or after, the transistor 680.

FIG. 8B is a flowchart of a method 800B, in accordance with some embodiments. In some embodiments, the method 800A is performed in or by one or more of the memory devices 100, 200A, 200B, 300, 400A-400C, 600B, 704. The method 800B comprises a first CIM operation 820, and a second CIM operation 830. In some embodiments, the second CIM operation 830 is omitted. The first CIM operation 820 comprises operations 822, 824, 826.

At operation 822, first input voltages are supplied to a plurality of word lines in each of at least two first memory arrays among a plurality of memory arrays of a memory device. For example, as described with respect to FIGS. 1D, 2A, for each of the two first memory arrays, e.g., Deck-1, Deck-2, first input voltages are supplied to read word lines RWL0-RWL3.

At operation 824, for each of the at least two first memory arrays, a first bit line current corresponding to a sum of currents, output by memory cells in response to the first input voltages supplied to the plurality of word lines, is collected on a first bit line coupled to the memory cells. For example, as described with respect to FIGS. 1D, 2A, first bit line currents I_{CIM,BL0,Deck-1}, I_{CIM,BL0,Deck-2}, are collected on the corresponding bit lines BL0 of the two first memory arrays, e.g., Deck-1, Deck-2.

At operation 826, a first path current corresponding to a sum of the first bit line currents of the at least two first memory arrays is collected. For example, as described with respect to FIG. 2A, a first path current I_{CIM,Path0} corresponding to a sum of the first bit line currents I_{CIM,BL0,Deck-1}, I_{CIM,BL0,Deck-2}, is collected on a conductor Path0. In some embodiments, the path current I_{CIM,Path0} is supplied to a sensing circuit, and based on the sensed path current, a result of the first CIM operation involving first input data corresponding to the first input voltages and first weight data stored in the two first memory arrays, e.g., Deck-1, Deck-2, is determined.

In the second CIM operation 830 in accordance with some embodiments, operations similar to operations 822, 824, 826 are performed for a different set of second memory arrays, e.g., Deck-3, Deck-4 in FIG. 2A. As a result, it is possible in one or more embodiments to perform different first and second CIM operations for different functions or applications, as described. One or more advantages described herein are achievable by the method 800B, in accordance with some embodiments.

The described methods and algorithms include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, a method comprises a first computing-in-memory (CIM) operation of a memory device. The memory device comprises a plurality of memory arrays. Each of the plurality of memory arrays comprises a first bit line, a plurality of word lines and a plurality of memory cells coupled to the first bit line and correspondingly to the plurality of word lines. In the first CIM operation, the method comprises supplying first input voltages to the plurality of word lines in each of at least two first memory arrays among the plurality of memory arrays. In the first CIM operation, the method further comprises, for each of the at least two first memory arrays, collecting, on the first bit line, a first bit line current corresponding to a sum of currents output by the plurality of memory cells on the first bit line in response to the first input voltages supplied to the plurality of word lines. In the first CIM operation, the method further comprises collecting a first path current corresponding to a sum of the first bit line currents of the at least two first memory arrays.

In some embodiments, a method comprises writing weight data in a plurality of memory arrays of a memory device. Each of the plurality of memory arrays comprises a first bit line, a plurality of word lines and a plurality of memory cells coupled to the first bit line and correspondingly to the plurality of word lines. The first bit lines of the plurality of memory arrays are electrically coupled to each other by a conductor. The method further comprises performing a computing-in-memory (CIM) operation comprising: supplying input voltages to the plurality of word lines in the plurality of memory arrays and, based on a path current on the conductor, determining a result of a computation involving input data corresponding to the input voltages and the weight data. The plurality of memory arrays comprises a first memory array and a second memory array. The method further comprises combining a first memory cell among the plurality of memory cells coupled to the first bit line in the first memory array with a corresponding second memory cell among the plurality of memory cells coupled to the first bit line in the second memory array into an equivalent memory cell with multi-level conductance to store part of the weight data.

In some embodiments, a method comprises writing weight data in a plurality of memory arrays of a memory device. Each of the plurality of memory arrays comprises a first bit line, a plurality of word lines and a plurality of memory cells coupled to the first bit line and correspondingly to the plurality of word lines. The first bit lines of the plurality of memory arrays are electrically coupled to each other by a conductor. The method further comprises performing a computing-in-memory (CIM) operation comprising: supplying input voltages to the plurality of word lines in the plurality of memory arrays and, based on a path current on the conductor, determining a result of a computation involving input data corresponding to the input voltages and the weight data. The plurality of memory arrays has different resistance-area products. The weight data comprise a plurality of weight data portions with different bit significances. The writing comprises writing each of plurality of weight data portions into a corresponding memory array among the plurality of memory arrays, in accordance with the different resistance-area products and the different bit significances.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
in a first computing-in-memory (CIM) operation of a memory device, the memory device comprising a plurality of memory arrays, each of the plurality of memory arrays comprising a first bit line, a plurality of word lines and a plurality of memory cells coupled to the first bit line and correspondingly to the plurality of word lines,
supplying first input voltages to the plurality of word lines in each of at least two first memory arrays among the plurality of memory arrays,
for each of the at least two first memory arrays, collecting, on the first bit line, a first bit line current corresponding to a sum of currents output by the plurality of memory cells on the first bit line in response to the first input voltages supplied to the plurality of word lines, and
collecting a first path current corresponding to a sum of the first bit line currents of the at least two first memory arrays.

2. The method of claim 1, further comprising:
sensing the first path current; and
based on the sensed first path current, determining a product of first input data corresponding to the first input voltages and first weight data stored in the plurality of memory cells of the at least two first memory arrays.

3. The method of claim 1, further comprising:
in a second CIM operation of the memory device, the second CIM operation different from the first CIM operation,
supplying second input voltages to the plurality of word lines in each of at least two second memory arrays among the plurality of memory arrays, the at least two second memory arrays different from the at least two first memory arrays,
for each of the at least two second memory arrays, collecting, on the first bit line, a second bit line current corresponding to a sum of currents output by the plurality of memory cells on the first bit line in response to the second input voltages supplied to the plurality of word lines, and
collecting a second path current corresponding to a sum of the second bit line currents of the at least two second memory arrays.

4. The method of claim 3, further comprising:
sensing the second path current; and
based on the sensed second path current, determining a product of second input data corresponding to the second input voltages and second weight data stored in the plurality of memory cells of the at least two second memory arrays.

5. The method of claim 3, wherein
the plurality of memory arrays is stacked one over another along a thickness direction of the memory device,
the first bit lines of the at least two first memory arrays are electrically coupled to each other by a first conductor which extends along the thickness direction, and along which the first path current is collected in the first CIM operation,
the first bit lines of the at least two second memory arrays are electrically coupled to each other by a second conductor which extends along the thickness direction, and along which the second path current is collected in the second CIM operation, and
the second conductor is electrically disconnected from the first conductor.

6. The method of claim 3, wherein
the plurality of memory arrays is stacked one over another along a thickness direction of the memory device, and
the first bit lines of all of the plurality of memory arrays are electrically coupled to each other by a conductor which extends along the thickness direction, and along which the first path current is collected in the first CIM operation and the second path current is collected in the second CIM operation.

7. The method of claim 1, wherein
the plurality of memory arrays is stacked one over another along a thickness direction of the memory device,
the first bit lines of all of the plurality of memory arrays are electrically coupled to each other by a conductor which extends along the thickness direction, and along which the first path current is collected in the first CIM operation,
the method further comprises:
switching the at least two first memory arrays among the plurality of memory arrays depending on the first CIM operation.

8. The method of claim 7, wherein
the switching comprises changing a number of memory arrays in the at least two first memory arrays in the first CIM operation.

9. The method of claim 1, wherein
the at least two first memory arrays have different resistance-area products, and
the method further comprises:
sensing the first path current;
obtaining the different resistance-area products or coefficients corresponding to the different resistance-area products predetermined and stored in a storage circuit; and
based on the sensed first path current and the stored different resistance-area products or coefficients, determining a product of first input data corresponding to the first input voltages and first weight data stored in the plurality of memory cells of the at least two first memory arrays.

10. The method of claim 9, further comprising:
storing most significant bit (MSB) weight data of the first weight data in, among the at least two first memory arrays, a memory array with a lowest resistance-area product; and
storing least significant bit (LSB) weight data of the first weight data in, among the at least two first memory arrays, a memory array with a highest resistance-area product.

11. A method, comprising:
writing weight data in a plurality of memory arrays of a memory device, wherein each of the plurality of memory arrays comprises a first bit line, a plurality of word lines and a plurality of memory cells coupled to the first bit line and correspondingly to the plurality of word lines, and the first bit lines of the plurality of memory arrays are electrically coupled to each other by a conductor; and
performing a computing-in-memory (CIM) operation comprising:
supplying input voltages to the plurality of word lines in the plurality of memory arrays, and
based on a path current on the conductor, determining a result of a computation involving input data corresponding to the input voltages and the weight data,
wherein
the plurality of memory arrays comprises a first memory array and a second memory array, and
the method further comprises:
combining a first memory cell among the plurality of memory cells coupled to the first bit line in the first memory array with a corresponding second memory cell among the plurality of memory cells coupled to the first bit line in the second memory array into an equivalent memory cell with multi-level conductance to store part of the weight data.

12. The method of claim 11, wherein
the plurality of memory arrays is stacked one over another along a thickness direction of the memory device, and
the first memory cell and the second memory cell are stacked one over another along the thickness direction.

13. The method of claim 11, wherein
the equivalent memory cell has
a first conductance level corresponding to both the first memory cell and the second memory cell having the first conductance level,
a second conductance level corresponding to both the first memory cell and the second memory cell having the second conductance level, and
at least one intermediate conductance level corresponding to the first memory cell having one of the first conductance level and the second conductance level, and the second memory cell having the other of the first conductance level and the second conductance level, and
the first conductance level, the second conductance level and the at least one intermediate conductance level are different from each other.

14. The method of claim 13, wherein
the first and second memory arrays have a same resistance-area product, and
the at least one intermediate conductance level is a single intermediate conductance level.

15. The method of claim 13, wherein
the first and second memory arrays have different resistance-area products, and
the at least one intermediate conductance level comprises two different intermediate conductance levels.

16. The method of claim 11, wherein
in the CIM operation, a same input voltage, among the input voltages, is supplied to the word lines correspondingly coupled to the first memory cell and the second memory cell.

17. A method, comprising:
writing weight data in a plurality of memory arrays of a memory device, wherein each of the plurality of memory arrays comprises a first bit line, a plurality of word lines and a plurality of memory cells coupled to the first bit line and correspondingly to the plurality of word lines, and the first bit lines of the plurality of memory arrays are electrically coupled to each other by a conductor; and
performing a computing-in-memory (CIM) operation comprising:
supplying input voltages to the plurality of word lines in the plurality of memory arrays, and
based on a path current on the conductor, determining a result of a computation involving input data corresponding to the input voltages and the weight data,
wherein
the plurality of memory arrays has different resistance-area products,
the weight data comprise a plurality of weight data portions with different bit significances, and
the writing comprises writing each of plurality of weight data portions into a corresponding memory array among the plurality of memory arrays, in accordance with the different resistance-area products and the different bit significances.

18. The method of claim 17, wherein
the writing comprises writing the plurality of weight data portions sorted in a decreasing order of the bit significances into the plurality of memory arrays sorted in an increasing order of the resistance-area products.

19. The method of claim 17, wherein
the writing comprises:
writing, among the plurality of weight data portions, a most significant bit (MSB) weight data portion into, among the plurality of memory arrays, a memory array with a lowest resistance-area product; and
writing, among the plurality of weight data portions, a least significant bit (LSB) weight data portion into, among the plurality of memory arrays, a memory array with a highest resistance-area product.

20. The method of claim 17, further comprising, in the CIM operation:
obtaining the different resistance-area products or coefficients corresponding to the different resistance-area products predetermined and stored in a storage circuit; and
based on the path current and the stored different resistance-area products or coefficients, determining the result of the computation involving the input data and the weight data.
